(19) United States
(12) Patent Application Publication
(10) Pub. No.: US 2026/0157006 A1
(43) Pub. Date: Jun. 4, 2026

(54) DISPLAY DEVICE AND ELECTRONIC APPARATUS

(71) Applicant: Samsung Display Co., Ltd., Yongin-si (KR)

(72) Inventor: Seungbin Lee, Yongin-si (KR)

(21) Appl. No.: 19/400,676

(22) Filed: Nov. 25, 2025

(30) Foreign Application Priority Data
Dec. 3, 2024 (KR) 10-2024-0177901

(51) Int. Cl. H10H 29/854; H10H 20/815; H10H 29/01; H10H 29/853

(52) U.S. Cl. CPC H10H 29/854; H10H 20/815; H10H 29/012; H10H 29/0362; H10H 29/853

(57) ABSTRACT

A display device and an electronic apparatus including the display device are disclosed. The display device may include a substrate, a plurality of transistors, a plurality of light-emitting diodes, an encapsulation layer arranged on the plurality of light-emitting diodes and including a first inorganic encapsulation layer, a second inorganic encapsulation layer, and an organic encapsulation layer, a plurality of inorganic insulating layers, a partition wall, an uneven structure arranged between the partition wall and the edge of the substrate, defined in the plurality of inorganic insulating layers, and including a plurality of protrusions and a groove between two adjacent protrusions, and a cover bank layer on the uneven structure, wherein the first inorganic encapsulation layer and the second inorganic encapsulation layer extend on the cover bank layer and are in direct contact with each other on the cover bank layer with being apart from the edge of the substrate.

### CROSS-REFERENCE TO RELATED APPLICATION

The present application claims priority to and the benefit of Korean Patent Application No. 10-2024-0177901, filed on Dec. 3, 2024, in the Korean Intellectual Property Office, the entire disclosure of which is incorporated herein by reference.

### BACKGROUND

### 1. Field

One or more embodiments of the present disclosure relate to a display device and an electronic apparatus including the display device.

### 2. Description of the Related Art

Recently, display devices have been used in electronic apparatuses for one or more suitable purposes. As the range of uses of display devices has widened, the demand or desire for high-quality display devices with excellent durability and various shapes has increased.

### SUMMARY

Cracks and other defects may easily occur internally due to external impact during the manufacturing process and/or during use after manufacturing.

One or more aspects of embodiments of the present disclosure are directed toward a display device that is robust against external impact and an electronic apparatus including the display device. However, such a technical aspect and/or feature is just an example, and embodiments of the present disclosure are not limited thereto.

Additional aspects of embodiments will be set forth in part in the description which follows and, in part, will be apparent from the description or may be learned by practice of the presented embodiments of the disclosure.

According to one or more embodiments, a display device includes a substrate including a display area and a peripheral area outside the display area, a plurality of transistors arranged in the display area of the substrate, a plurality of light-emitting diodes arranged in the display area of the substrate and electrically connected to the plurality of transistors, an encapsulation layer arranged on the plurality of light-emitting diodes and including a first inorganic encapsulation layer, a second inorganic encapsulation layer over the first inorganic encapsulation layer, and an organic encapsulation layer between the first inorganic encapsulation layer and the second inorganic encapsulation layer, a plurality of inorganic insulating (e.g., electrically insulating) layers arranged in the peripheral area of the substrate and apart from an edge of the substrate, a partition wall arranged in the peripheral area of the substrate, an uneven structure located or arranged between the partition wall and the edge of the substrate, defined in the plurality of inorganic insulating layers, and including a plurality of protrusions and a groove between two adjacent protrusions among the plurality of protrusions, and a cover bank layer on the uneven structure, wherein an edge of the organic encapsulation layer is located or arranged on one side of the partition wall, and each of the first inorganic encapsulation layer and the second inorganic encapsulation layer extends on the cover bank layer and is apart from (e.g., space from) the edge of the substrate.

An edge of the second inorganic encapsulation layer may be located or arranged between an edge of the first inorganic encapsulation layer and the edge of the substrate.

An edge of the first inorganic encapsulation layer and an edge of the second inorganic encapsulation layer may be substantially aligned on the same line.

The first inorganic encapsulation layer may be in direct contact with the second inorganic encapsulation layer on the cover bank layer.

The plurality of inorganic insulating layers may include a buffer layer arranged between the substrate and a semiconductor layer of each of the plurality of transistors, and an edge of the buffer layer may be apart from (e.g., space from) the edge of the substrate.

A bottom surface of the groove may correspond to an upper surface of the buffer layer.

A bottom surface of the groove may correspond to an upper surface of the substrate.

The substrate may include a first polymer resin layer, a first inorganic barrier layer on the first polymer resin layer, a second polymer resin layer on the first inorganic barrier layer, and a second inorganic barrier layer on the second polymer resin layer, wherein the edge of the substrate may be defined by an edge of at least one selected from among the first polymer resin layer, the first inorganic barrier layer, and the second polymer resin layer, and wherein an edge of the second inorganic barrier layer may be apart from (e.g., space from) the edge of the at least one selected from among the first polymer resin layer, the first inorganic barrier layer, and the second polymer resin layer.

The groove may extend to the second inorganic barrier layer.

According to one or more embodiments, an electronic apparatus includes a display device including a display area and a peripheral area, and a lower cover forming an exterior, the lower cover including, in a front surface of the lower cover, an opening exposing a portion of the display device, and the lower cover overlapping the peripheral area of the display device, wherein the display device includes a substrate, a plurality of transistors arranged on the substrate to correspond to the display area, a plurality of light-emitting diodes arranged on the substrate to correspond to the display area and electrically connected to the plurality of transistors, an encapsulation layer arranged on the plurality of light-emitting diodes and including a first inorganic encapsulation layer, a second inorganic encapsulation layer over the first inorganic encapsulation layer, and an organic encapsulation layer between the first inorganic encapsulation layer and the second inorganic encapsulation layer, a plurality of inorganic insulating (e.g., electrically insulating) layers arranged in the peripheral area of the substrate and apart from (e.g., space from) an edge of the substrate, a partition wall arranged in the peripheral area of the substrate, an uneven structure located or arranged between the partition wall and the edge of the substrate, defined in the plurality of inorganic insulating layers, and including a plurality of protrusions and a groove between two adjacent protrusions among the plurality of protrusions, and a cover bank layer on the uneven structure, wherein an edge of the organic encapsulation layer is located or arranged on one side of the partition wall, and each of the first inorganic encapsulation layer and the second inorganic encapsulation layer extends on the cover bank layer, and an edge of the first inorganic encapsulation layer and an edge of the second inorganic encapsulation layer are apart from (e.g., space from) the edge of the substrate, and wherein a portion of a region of the substrate that corresponds to the peripheral area is bent to have curvature.

The edge of the second inorganic encapsulation layer may be located or arranged between the edge of the first inorganic encapsulation layer and the edge of the substrate.

The edge of the first inorganic encapsulation layer and the edge of the second inorganic encapsulation layer may be substantially aligned on the same line.

The first inorganic encapsulation layer may be in direct contact with the second inorganic encapsulation layer, on the cover bank layer.

The plurality of inorganic insulating layers may include a buffer layer arranged between the substrate and a semiconductor layer of each of the plurality of transistors, and an edge of the buffer layer may be apart from (e.g., space from) the edge of the substrate.

A bottom surface of the groove may correspond to an upper surface of the buffer layer.

A bottom surface of the groove may correspond to an upper surface of the substrate.

The substrate may include a first polymer resin layer, a first inorganic barrier layer on the first polymer resin layer, a second polymer resin layer on the first inorganic barrier layer, and a second inorganic barrier layer on the second polymer resin layer, wherein the edge of the substrate may be defined by an edge of at least one selected from among the first polymer resin layer, the first inorganic barrier layer, and the second polymer resin layer, and wherein an edge of the second inorganic barrier layer may be apart from (e.g., space from) an edge of the at least one selected from among the first polymer resin layer, the first inorganic barrier layer, and the second polymer resin layer.

The edge of the second inorganic encapsulation layer and the edge of the second inorganic barrier layer may be substantially aligned on the same line.

The groove may extend to the second inorganic barrier layer.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a perspective view of an electronic apparatus according to one or more embodiments;

FIG. 2 is an exploded perspective view of an electronic apparatus according to one or more embodiments;

FIG. 3 is a block diagram of an electronic apparatus according to one or more embodiments;

FIG. 4 is a schematic plan view of a display device according to one or more embodiments;

FIGS. 5 and 6 are schematic side views of a display device according to one or more embodiments;

FIG. 7 is a schematic cross-sectional view of a display device according to one or more embodiments;

FIG. 8 is an excerpted plan view of an uneven structure and a cover bank layer of a display device according to one or more embodiments;

FIG. 9 is a schematic side view of an assembled state of a display device and a lower cover as an electronic apparatus according to one or more embodiments;

FIGS. 10A-10C are cross-sectional views each being of an uneven structure and a cover bank layer of a display device according to one or more embodiments;

FIG. 11 is a schematic cross-sectional view of a display device according to one or more embodiments;

FIGS. 12A-12C are cross-sectional views each being of an uneven structure and a cover bank layer of a display device according to one or more embodiments;

FIGS. 13A and 13B are cross-sectional views illustrating a process of manufacturing a display device according to one or more embodiments;

FIGS. 14A and 14B are cross-sectional views illustrating a process of manufacturing a display device according to one or more embodiments; and

FIG. 15 is a perspective view of an electronic apparatus that employs a display device according to one or more embodiments.

### DETAILED DESCRIPTION

Reference will be made in more detail to one or more embodiments, examples of which are illustrated in the accompanying drawings, wherein like reference numerals refer to like elements throughout the attached drawings and the written description, and duplicative descriptions thereof may not be provided in the specification. In this regard, the subject matter of the present disclosure may be embodied in different forms and should not be construed as being limited to one or more embodiments set forth herein. Rather, these embodiments are provided as examples, by referring to the drawings, to explain the aspects and features of the present disclosure to those skilled in the art.

As used herein, the term “and/or” includes any and all combinations of one or more of the associated listed items.

The utilization of “may” when describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

Throughout the present disclosure, the expression “at least one of a, b, or c” or “at least one selected from among a, b, and c” indicates only a, only b, only c, both (e.g., simultaneously) a and b, both (e.g., simultaneously) a and c, both (e.g., simultaneously) b and c, all of a, b, and c, or variations thereof.

As the present disclosure allows for one or more suitable changes to the disclosed subject matter and embodiments, certain embodiments will be illustrated in the accompanying drawings and described in more detail in the written description. The aspects, effects, and/or embodiments of the present disclosure and methods for achieving them will be clarified with reference to one or more embodiments and the accompanying drawings described below in more detail. However, the disclosure is not limited to disclosed embodiments and may be embodied in one or more suitable forms.

While such terms as “first,” “second,” and/or the like may be used to describe one or more suitable elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “has,” “having,” “include,” and/or “including” as used herein specify the presence of stated features or elements but do not preclude the addition of one or more other features or elements. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be further understood that, if (e.g., when) a layer, a region, or an element is referred to as being “on” another layer, region, or element, it may be directly or indirectly on the other layer, region, or element. For example, for example, intervening layers, regions, or elements may be present therebetween. In contrast, if (e.g., when) a layer, a region, or an element is referred to as being “directly on” another layer, region, or element, there may be no intervening layers, regions, or elements present therebetween.

The sizes of elements in the drawings may be exaggerated or reduced for convenience of explanation. As an example, the size and thickness of each element shown in the drawings may be arbitrarily represented for convenience of description, and thus, embodiments of the present disclosure are not necessarily limited thereto.

In the case where a certain embodiment may be implemented differently, a specific process order may be performed in the order different from the described order. As an example, two processes successively described may be concurrently (e.g., simultaneously) performed substantially or performed in the opposite order.

It will be understood that if (e.g., when) a layer, a region, or a component is referred to as being “connected” to another layer, region, or component, it may be “directly connected” to the other layer, region, or component or may be “indirectly connected” to the other layer, region, or component with other layer, region, or component arranged therebetween. For example, it will be understood that if (e.g., when) a layer, a region, or an element is referred to as being “electrically connected” to another layer, region, or element, it may be “directly electrically connected” to the other layer, region, or element or may be “indirectly electrically connected” to the other layer, region, or element with another layer, region, or element arranged therebetween.

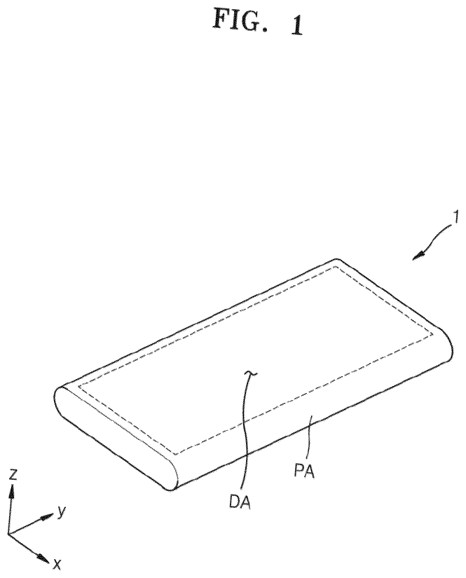

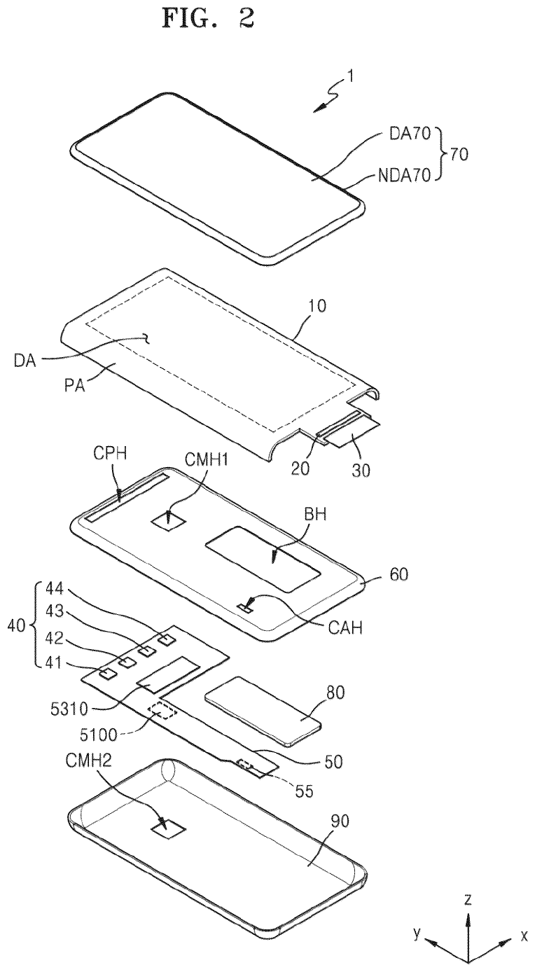

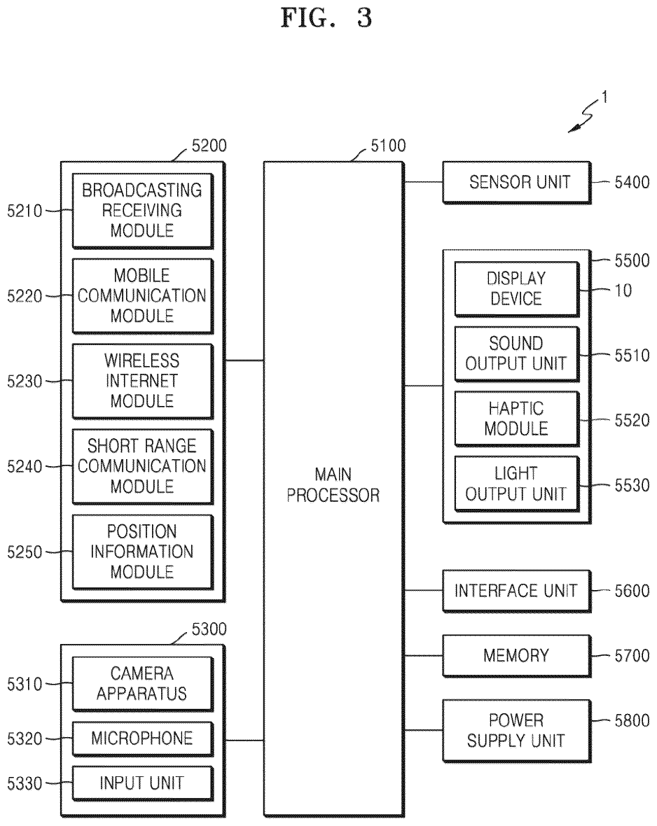

FIG. 1 is a perspective view of an electronic apparatus 1 according to one or more embodiments, FIG. 2 is an exploded perspective view of the electronic apparatus 1 according to one or more embodiments, and FIG. 3 is a block diagram of the electronic apparatus 1 according to one or more embodiments.

Referring to FIGS. 1 and 2, the electronic apparatus 1 according to one or more embodiments may display moving images and/or still images. The electronic apparatus 1 according to one or more embodiments may include a cover window 70, a display device 10, a data driver 20, a display circuit board 30, a component 40, a bracket 60, a main circuit board 50, a battery 80, and a lower cover 90.

In a plan view of the present specification, “left”, “right”, “up”, and “down” denote directions if (e.g., when) the display device 10 is viewed from a direction normal (e.g., perpendicular) to the display device 10. As an example, “left” denotes a-x direction, “right” denotes a +x direction, “up” denotes a +y direction, and “down” denotes a-y direction.

The electronic apparatus 1 may have a rectangular shape (e.g., a substantially rectangular shape) in a plan view. As an example, as illustrated in FIG. 1, the electronic apparatus 1 may have a quadrangular shape (e.g., a substantially quadrangular shape) having short sides in the x direction and long sides in the y direction in a plan view. A corner where the short side in the x direction meets the long side in the y direction may be round to have a preset (e.g., set or predetermined) curvature or formed to have a right angle. A planar shape (e.g., a substantially planar shape) of the electronic apparatus 1 is not limited to a rectangle (e.g., a substantially rectangle), but may be other polygons (e.g., substantially polygons), ellipses (e.g., substantially ellipses), or irregular shapes.

The cover window 70 may be arranged on the display device 10 to cover the upper surface of the display device 10. Accordingly, the cover window 70 may be to protect the upper surface of the display device 10.

The cover window 70 may include a transmissive cover portion DA70 and a light-blocking cover portion NDA70, wherein the transmissive cover portion DA70 corresponds to a display area DA of the display device 10, and the light-blocking cover portion NDA70 is around (e.g., surrounds) the transmissive cover portion DA70. The light-blocking cover portion NDA70 may include an opaque material (e.g., a colored opaque material) that blocks light. The light-blocking cover portion NDA70 may overlap a peripheral area PA of the display device 10.

The display device 10 may be arranged under the cover window 70. The display device 10 may include the display area DA and the peripheral area PA outside the display area DA. The display area DA may be a region in which images are displayed. In one or more embodiments, the display area DA may include a region (referred to as a component area, hereinafter) that is to transmit light emitted from the component 40 arranged below the display device 10. The component 40 may include sensors and cameras that are to use visible light, infrared light, sound, and/or the like.

The display device 10 may be a light-emitting display device including a light-emitting diode. The light-emitting diode may include an organic light-emitting diode including an organic emission layer. The light-emitting diode may be an inorganic light-emitting diode including an inorganic material. The inorganic light-emitting diode may include a PN diode (or p-n diode or p-n junction diode) including inorganic material semiconductor-based materials. If (e.g., when) a forward voltage is applied to a PN-junction diode, holes and electrons may be injected and energy created by recombination of the holes and the electrons may be converted to light energy, and thus, light of a preset (e.g., set or predetermined) color may be emitted. The inorganic light-emitting diode may have a width in the range of several micrometers to hundreds of micrometers. In one or more embodiments, the inorganic light-emitting diode may be denoted by a micro light-emitting diode.

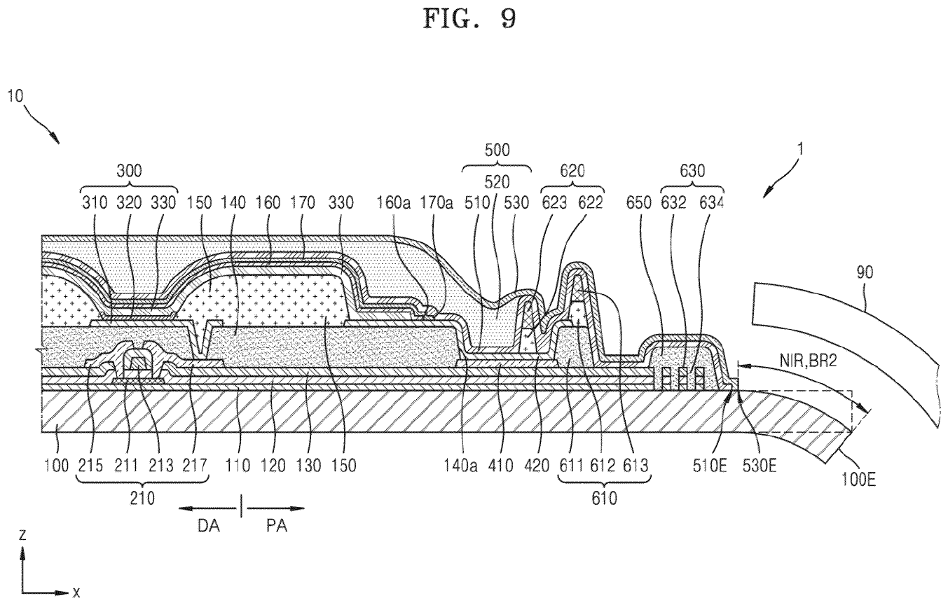

The display device 10 may be a rigid display device having rigidity or a flexible display device that is flexible and easily bent. In one or more embodiments, the display device 10 may be assembled between the cover window 70 and the lower cover 90 with a portion of the peripheral area PA bent. For example, it is illustrated in FIG. 2 that a portion of the peripheral area PA of the display device 10 arranged on two opposite sides of the display area DA may be bent with a curvature. A bent portion of the peripheral area PA of the display device 10 may overlap the lower cover 90, and a specific structure thereof is described in more detail herein with reference to FIG. 9.

The data driver 20 may be arranged in the form of an integrated circuit (IC) on the display device 10. In one or more embodiments, the data driver 20 may be arranged on the display circuit board 30.

The display circuit board 30 may be attached on one side of the display device 10. The display circuit board 30 may be a flexible printed circuit board (FPCB) that may be bent, a rigid printed circuit board (PCB) that is strong and not easily bent, or a composite printed circuit board including both (e.g., simultaneously) a rigid printed circuit board and a flexible printed circuit board.

In one or more embodiments, a touch sensor driver may be arranged on the display circuit board 30. The touch sensor driver may include an integrated circuit. The touch sensor driver may be attached to the display circuit board 30. The touch sensor driver may be electrically connected to touch electrodes of a touchscreen layer of the display device 10 through the display circuit board 30.

The touchscreen layer of the display device 10 may be to sense a user's touch input by using at least one of one or more suitable touch methods, such as a resistance layer method, a capacitance method, and/or the like. As an example, in the case where the touchscreen layer of the display device 10 senses a user's touch input by using a capacitance method, the touch sensor driver may be to determine whether a user touches the touchscreen layer by applying driving signals to driving electrodes among touch electrodes, and sensing voltages charged in a mutual capacitance between the driving electrodes and the sensing electrodes through the sensing electrodes among the touch electrodes. A user's touch may include a contact touch and/or a proximity touch. A contact touch denotes that an object, such as a user's finger and/or a pen, is in direct contact with the cover window 70 arranged on the touchscreen layer. A proximity touch, such as hovering, denotes that an object, such as a user's finger and/or a pen, may be located or arranged near over the cover window 70, away from the cover window 70. The touch sensor driver may be arranged to transfer sensor data to a main processor 5100 according to sensed voltages, and the main processor 5100 may be arranged to calculate touch coordinates at which a touch input occurs by analyzing the sensor data.

A controller may be arranged on the display circuit board 30, wherein the controller is arranged to supply driving voltages to drive pixels of the display device 10, a gate driver, and the data driver 20.

The bracket 60 to support the display device 10 may be arranged under the display device 10. The bracket 60 may include plastic, metal, or both (e.g., simultaneously) plastic and metal. A first camera hole CMH1 in which a camera apparatus 5310 is inserted, a battery hole BH in which a battery 80 is arranged, and a cable hole CAH through which a cable connected to the display circuit board 30 passes may be formed or arranged in the bracket 60. A component hole CPH that overlaps the display device 10 may be provided in the bracket 60. The component hole CPH may overlap the components 40 of the main circuit board 50 in a third direction (e.g., z direction). In one or more embodiments, the display area DA of the display device 10 may overlap the components 40 of the main circuit board 50 in the third direction (e.g., z direction). In one or more embodiments, the component hole CPH may not be formed or arranged in the bracket 60.

In one or more embodiments, the components 40 may include a first component 41, a second component 42, a third component 43, and a fourth component 44 each overlapping the display device 10. The first component 41, the second component 42, the third component 43, and the fourth component 44 may include a proximity sensor, an illuminance sensor, an iris sensor, a face recognition sensor, and a camera (or an image sensor). A proximity sensor that uses an infrared ray may be to detect an object arranged close to the upper surface of the electronic apparatus 1, and an illuminance sensor may be to detect brightness of light incident to the upper surface of the electronic apparatus 1. In one or more embodiments, an iris sensor may be to capture a person's iris arranged over the upper surface of the electronic apparatus 1, and a camera may be to capture an object arranged on the upper surface of the electronic apparatus 1. The component 40 is not limited to the proximity sensor, the illuminance sensor, the iris sensor, the face recognition sensor, and the camera. One or more suitable sensors as described herein may be arranged.

The main circuit board 50 and the battery 80 may be arranged under the bracket 60. The main circuit board 50 may be a rigid printed circuit board or a flexible printed circuit board.

The main circuit board 50 may include the main processor 5100, the camera apparatus 5310, a main connector 55, and the components 40. The main processor 5100 may include an integrated circuit. The camera apparatus 5310 may be arranged on both (e.g., simultaneously) the upper surface and the lower surface of the main circuit board 50, and the main processor 5100 and the main connector 55 may each be arranged on one selected from the upper surface and the lower surface of the main circuit board 50.

The main processor 5100 may be arranged to control all functions of the electronic apparatus 1. As an example, the main processor 5100 may be arranged to output digital video data to the data driver 20 through the display circuit board 30 such that the display device 10 displays images. The main processor 5100 may be arranged to receive sensed data from the touch sensor driver. The main processor 5100 may be to determine whether a user touches a touchscreen layer according to sensed data and execute an operation that corresponds to a user's direct touch and/or proximity touch. The main processor 5100 may be an application processor including an integrated circuit, a central processing unit, or a system chip.

The camera apparatus 5310 may be to process image frames, such as still images and/or moving images, obtained by an image sensor in a camera mode and output the image frames to the main processor 5100. The camera apparatus 5310 may include at least one selected from among a camera sensor (e.g., a charge-coupled device (CCD), a complementary metal oxide semiconductor (CMOS), and/or the like), a photo sensor (or an image sensor), and/or a laser sensor. The camera apparatus 5310 may be connected to an image sensor among the components 40 that overlap the display area DA and may be to process images input to the image sensor.

The cable that passes through the cable hole CAH of the bracket 60 may be connected to the main connector 55, and thus, the main circuit board 50 may be electrically connected to the display circuit board 30.

The main circuit board 50 may further include a wireless communication unit 5200, an input unit 5300, a sensor unit 5400, an output unit 5500, an interface unit 5600, a memory 5700, and/or a power supply unit 5800 as illustrated in FIG. 3 in addition to the main processor 5100, the camera apparatus 5310, and the main connector 55.

The wireless communication unit 5200 may include at least one selected from among a broadcasting receiving module 5210, a mobile communication module 5220, a wireless internet module 5230, a short range communication module 5240, and/or a position information module 5250.

The broadcasting receiving module 5210 may be arranged to receive broadcasting signals and/or broadcasting-related information from an external broadcasting management server through a broadcasting channel. The broadcasting channel may include satellite channels and groundwave channels.

The mobile communication module 5220 may be arranged to transmit/receive radio signals to/from at least one selected from among a base station, an external terminal, and/or a server on a mobile communication network established according to technology standards for mobile communication or communication schemes (e.g., Global System for Mobile communication (GSM), Code Division Multi Access (CDMA), Code Division Multi Access 2000 (CDMA 2000), Enhanced Voice-Data Optimized or Enhanced Voice-Data Only (EV-DO), Wideband CDMA (WCDMA), High Speed Downlink Packet Access (HSDPA), High Speed Uplink Packet Access(HSUPA), Long Term Evolution (LTE), Long Term Evolution-Advanced (LTE-A), and/or the like). Wireless signals may include voice call signals, image communication call signals, and/or one or more suitable types (kinds) of data that correspond to text/multimedia message transmission/reception.

The wireless internet module 5230 denotes a module for wireless internet access. The wireless internet module 5230 may be arranged to transmit/receive radio signals on a communication network according to wireless internet technologies. Examples of wireless internet technologies may include wireless local area network (WLAN), wireless-fidelity (Wi-Fi), Wi-Fi Direct, and/or digital living network alliance (DLNA).

The short range communication module 5240 may be for short range communication and may be to support short range communication by using at least one selected from among Bluetooth, Radio Frequency Identification (RFID), Infrared Data Association (IrDA), Ultra Wideband (UWB), ZigBee, Near Field Communication (NFC), Wi-Fi, Wi-Fi Direct, and/or Wireless Universal Serial Bus (Wireless USB) technologies. The short range communication module 5240 may be to support wireless communication between the electronic apparatus 1 and a wireless communication system, between the electronic apparatus 1 and another electronic apparatus, or between the electronic apparatus 1 and a network in which another electronic apparatus (or an external server) is located or arranged, through a short range wireless area network. The short range wireless area network may be a wireless personal area network. The other electronic apparatus may be a wearable device that may be to exchange data or operate with the electronic apparatus 1.

The position information module 5250, which is a module to obtain a location (or current location) of the electronic apparatus 1, may include a global positioning system (GPS) module or a Wi-Fi module.

The input unit 5300 may include an image input unit, such as the camera apparatus 5310 to input image signals, a sound input unit, such as a microphone 5320 to input sound signals, and an input module 5330 to receive information from a user.

The camera apparatus 5310 may be to process image frames, such as still images and/or moving images, obtained by an image sensor in an image communication mode or a capturing mode. The processed image frames may be displayed on the display device 10 or stored in the memory 5700.

The microphone 5320 may be to process external sound signals as electrical voice data. The processed voice data may be suitably utilized according to a function (or an application in execution) being performed in the electronic apparatus 1.

The main processor 5100 may be to control an operation of the electronic apparatus 1 to correspond to information input through the input module 5330. The input module 5330 may include a mechanical input means, such as buttons, a dome switch, a jog wheel, a jog switch, and/or the like, and/or a touch input means located or arranged on the lower surface and/or the lateral surface of the electronic apparatus 1. The touch input means may include the touchscreen layer of the display device 10.

The sensor unit 5400 may include at least one sensor that is to sense at least one selected from among information inside the electronic apparatus 1, peripheral environmental information around (e.g., surrounding) the electronic apparatus 1, and/or user information and generate sensing signals that correspond thereto. The main processor 5100 may be to control driving or an operation of the electronic apparatus 1 based on the sensing signals or perform data processing, a function, or an operation related to an application installed in the electronic apparatus 1. The sensor unit 5400 may include at least one selected from among a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, and/or the like), and/or a chemical sensor (e.g., an electronic nose, a healthcare sensor, a biometric sensor, and/or the like).

The output unit 5500 may be to generate an output related to a visual sense, an auditory sense, and/or a tactile sense and may include at least one selected from among the display device 10, a sound output unit 5510, a haptic module 5520, and/or a light output unit 5530.

The display device 10 may be to display (or output) information processed by the electronic apparatus 1. As an example, the display device 10 may be to display execution screen information of an application driven in the electronic apparatus 1 or user interface (UI) and graphic user interface (GUI) information that correspond to execution screen information. The display device 10 may include a display layer and the touchscreen layer, wherein the display layer is to display images, and the touchscreen layer is to sense a user's touch input. Accordingly, the display device 10 may be to serve as one of the input module 5330 that are to provide an input interface between the electronic apparatus 1 and a user and concurrently (e.g., simultaneously) to serve as one of the output units 5500 that are to provide an output interface between the electronic apparatus 1 and a user.

The sound output unit 5510 may be to output sound data received by the wireless communication unit 5200 or stored in the memory 5700 in a call reception mode, a communication mode or recording mode, a voice recognition mode, a broadcasting reception mode, and/or the like. The sound output unit 5510 may be to output sound signals related to a function (e.g., a call signal reception tone, a message reception tone, and/or the like) performed by the electronic apparatus 1. The sound output unit 5510 may include a receiver and a speaker. At least one selected from the receiver and the speaker may be a sound generator that is attached under the display device 10 and vibrates the display device 10 to output sounds. The sound generator may be a piezoelectric element or a piezoelectric actuator that contracts and expands according to electrical signals or an exciter that generates magnetic force by using a voice coil to vibrate the display device 10.

The haptic module 5520 may be to generate one or more suitable haptic effects that may be felt by a user. The haptic module 5520 may be to provide vibrations to a user as a haptic effect. The haptic module 5520 may not only be to transfer a tactile effect through a direct contact but be to implement a tactile effect such that a user may feel the tactile effect through a muscle sense in fingers and/or arms.

The light output unit 5530 may be to output signals to inform occurrence of an event by using light of a light source. Examples of an event generated in the electronic apparatus 1 may include message reception, call signal reception, a missed call, alarm, schedule notification, e-mail reception, information reception through an application, and/or the like. Signals output by the light output unit 5530 may be implemented if (e.g., when) the electronic apparatus 1 emits light of a single color or a plurality of colors to the front surface or the rear surface. The signal output may end if (e.g., when) the electronic apparatus 1 detects that a user confirms an event.

The interface unit 5600 may be to serve as a path with one or more suitable kinds (or types) of external apparatuses connected to the electronic apparatus 1. The interface unit 5600 may include at least one selected from among a wired/wireless headset port, an external charger port, a wired/wireless data port, a memory card part, a port to connect an apparatus having an identification module, an audio input/output (I/O) port, a video I/O port, and/or an earphone port. If (e.g., when) an external apparatus is connected to the interface unit 5600, the electronic apparatus 1 may perform an appropriate or suitable control related to the external apparatus connected.

The memory 5700 may be to store data that support one or more suitable functions of the electronic apparatus 1. The memory 5700 may be to store a plurality of application programs driven in the electronic apparatus 1, and data and commands for operations of the electronic apparatus 1. At least one or more of the plurality of application programs may be downloaded from an external server through wireless communication. The memory 5700 may be to store an application program for operations of the main processor 5100 and temporarily store data input/output, for example, data, such as a phone book, messages, still images, moving images, and/or the like. In one or more embodiments, the memory 5700 may be to store haptic data for one or more suitable patterns of vibrations provided to the haptic module 5520 and sound data regarding one or more suitable sounds provided to the sound output unit 5510. The memory 5700 may include at least one type (kind) of storing medium among a flash memory type (kind), a hard disk type (kind), a solid state disk (SSD) type (kind), a silicon disk drive (SDD) type (kind), a multimedia card micro type (kind), a card type (kind) memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and/or an optical disk.

The power supply unit 5800 may be to receive an external power and an internal power under control of the main processor 5100 and supply power to respective elements included in the electronic apparatus 1. The power supply unit 5800 may include the battery 80. In one or more embodiments, the power supply unit 5800 may include a connection port. The connection port may be arranged as an example of the interface unit 5600 to which an external charger is electrically connected, wherein the external charger supplies power to charge the battery 80. In one or more embodiments, the power supply unit 5800 may be arranged to charge the battery 80 wirelessly without using the connection port. The battery 80 may be arranged not to overlap the main circuit board 50 in the third direction (e.g., the z direction). The battery 80 may overlap the battery hole BH of the bracket 60.

The lower cover 90 may be arranged under the main circuit board 50 and the battery 80. The lower cover 90 may be fastened and fixed to the bracket 60. The lower cover 90 may form the lower exterior of the electronic apparatus 1. The lower cover 90 may include plastic, metal, or both (e.g., simultaneously) plastic and metal.

A second camera hole CMH2 through which the lower surface of the camera apparatus 5310 is exposed may be formed or arranged in the lower cover 90. The positions of the camera apparatus 5310 and the first camera hole CMH1 and the second camera hole CMH2 that correspond to the camera apparatus 5310 are not limited to one or more embodiments as illustrated in FIGS. 1 and 2, but may be suitably modified.

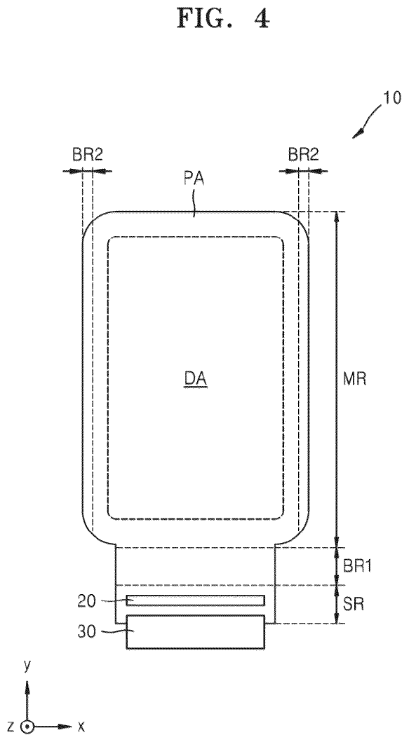

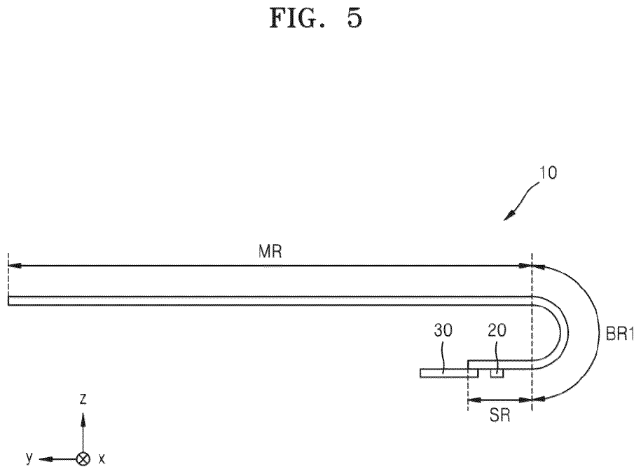

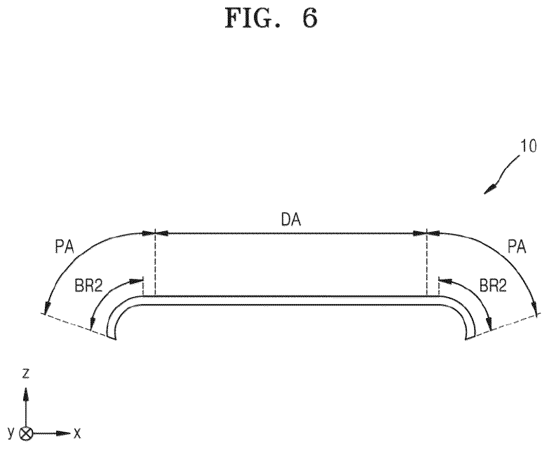

FIG. 4 is a schematic plan view of a display device 10 according to one or more embodiments, and FIGS. 5 and 6 are schematic side views of the display device 10 according to one or more embodiments.

The display device 10 may include the display area DA and the peripheral area PA outside the display area DA. The display area DA may be a region in which images are displayed, and a plurality of pixels may be arranged in the display area DA. The display area DA may have one or more suitable shapes, for example, circular shapes (e.g., substantially circular shapes), elliptical shapes (e.g., substantially elliptical shapes), polygonal shapes (e.g., substantially polygonal shapes), or shapes of specific drawings. As an example, it is illustrated in FIG. 4 that the display area DA may have a substantially rectangular shape having round corners.

The peripheral area PA may be arranged outside the display area DA. The peripheral area PA may be around (e.g., surround) at least a portion of the display area DA. As an example, the peripheral area PA may be around (e.g., surround) the display area DA entirely (e.g., substantially entirely).

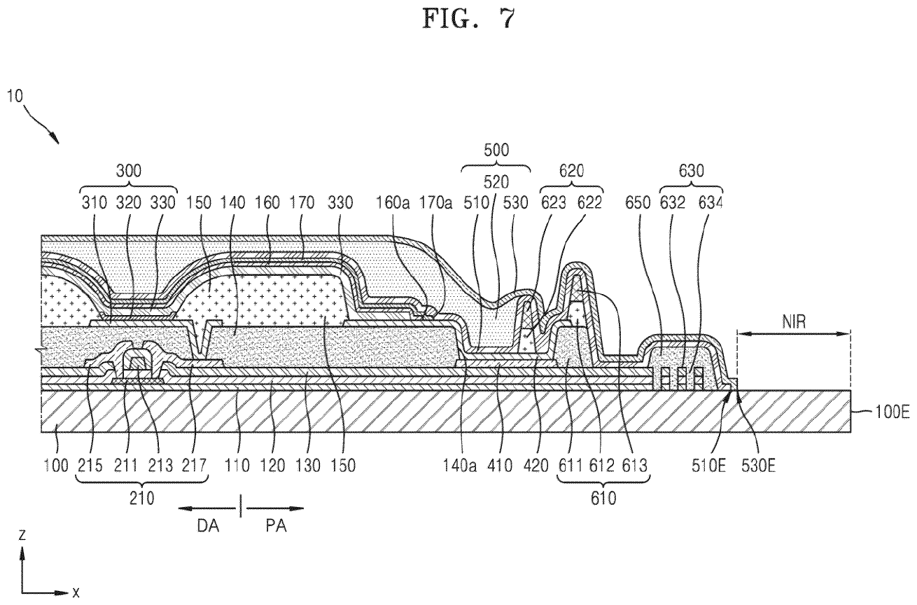

A planar shape (e.g., a substantially planar shape) of the display device 10 as illustrated in FIG. 4 may be substantially equal to the shape of the substrate 100 (see FIG. 7) included in the display device 10. If (e.g., when) the display device 10 includes the display area DA and the peripheral area PA outside the display area DA, it may represent that the substrate 100 (see FIG. 7) includes the display area DA and the peripheral area PA outside the display area DA. Hereinafter, for convenience, description is made on the assumption that the substrate 100 includes the display area DA and the peripheral area PA.

The display device 10 may include a main region MR, a first bent region BR1 outside the main region MR, and a sub-region SR apart from (e.g., space from) the main region MR with the first bent region BR1 therebetween. The main region MR may be arranged on one side of the first bent region BR1, and the sub-region SR may be arranged on the other side of the fist bent region BR1. The display device 10 may be bent in the first bent region BR1, as illustrated in FIG. 5, and if (e.g., when) viewed from the third direction (e.g., z direction), at least portion of the sub-region SR may overlap the main region MR. The main region MR may include the display area DA and a portion of the peripheral area PA around (e.g., surrounding) the display area DA. The first bent region BR1 and the sub-region SR may be a non-display area in which images are not displayed and may include another portion of the peripheral area PA.

Referring to FIGS. 4 and 5, it is illustrated in FIG. 5 that a portion of the peripheral area PA of the display device 10 may be bent around an axis that extends in the first direction (e.g., x direction), embodiments of the present disclosure are not limited thereto. As illustrated in FIG. 6, portions of the peripheral area PA arranged on two opposite sides of the display area DA with the display area DA therebetween, for example, second bent regions BR2, may each be bent with a preset (e.g., set or predetermined) curvature around an axis that extends in the second direction (e.g., y direction). Each of the bent portions of the peripheral area PA may be arranged inside the lower cover 90 (see FIG. 2) as described in one or more embodiments with reference to FIG. 2 and may overlap a portion (e.g., lateral surface) of the lower cover 90 (see FIG. 2).

Referring to FIG. 4, the data driver 20 may be arranged in the peripheral area PA, for example, the sub-region SR. The data driver 20 may be arranged in the form of an integrated circuit (IC) on the display device 10. As an example, the data driver 20 may be a data driving integrated circuit generating data signals.

The display circuit board 30 may be attached to the end of the sub-region SR of the display device 10. The display circuit board 30 may be electrically connected to the data driver 20 and/or the like through a pad of the sub-region SR of the display device 10.

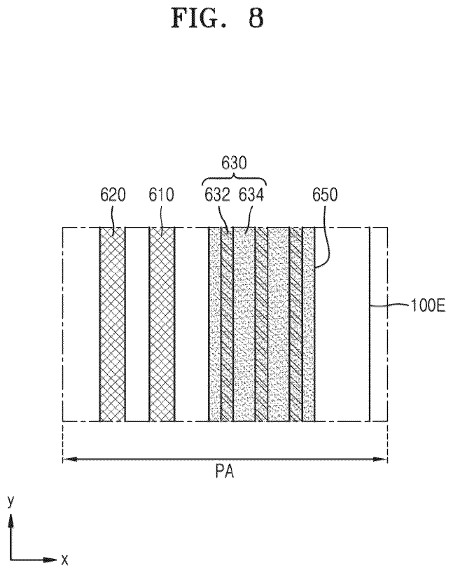

FIG. 7 is a schematic cross-sectional view of the display device 10 according to one or more embodiments, and FIG. 8 is an excerpted plan view of an uneven structure 630 and a cover bank layer 650 of the display device 10 according to one or more embodiments.

Referring to FIG. 7, the display device 10 may include the substrate 100. One or more suitable elements that form the display device 10 may be arranged on the substrate 100.

The substrate 100 may include glass, metal, and/or a polymer resin. The glass may include ultra-thin glass. The polymer resin may include, for example, polyethersulfone, polyacrylate, polyetherimide, polyethylene naphthalate, polyethylene terephthalate, polyphenylene sulfide, polyarylate, polyimide, polycarbonate, and/or cellulose acetate propionate. In one or more embodiments, the substrate 100 may include a single layer (e.g., single-layered structure) including glass, metal, and/or a polymer resin. In one or more embodiments, the substrate 100 may have a multi-layered structure including two resin layers including the polymer resin as described in one or more embodiments and an inorganic barrier layer arranged therebetween.

The pixels may be arranged in the display area DA, and the display area DA may be to display images using light emitted from the pixels. Each pixel may include a light-emitting diode 300, and the light-emitting diode 300 may be a light-emitting diode including an organic material, a light-emitting diode including an inorganic material, or a light-emitting diode including quantum dots. The light-emitting diode 300 may be arranged in the display area DA and electrically connected to a transistor 210 arranged in the display area DA.

The transistor 210 may include a semiconductor layer 211, a gate electrode 213, a source electrode 215, and a drain electrode 217, wherein the semiconductor layer 211 includes amorphous (e.g., non-crystalline) silicon, polycrystalline silicon, an oxide semiconductor, and/or an organic semiconductor material. To planarize the surface of the substrate 100 and/or prevent impurities and/or the like from penetrating the semiconductor layer 211 (or reduce a degree to or occurrence of which impurities and/or the like penetrate the semiconductor layer 211), a buffer layer 110 including an inorganic insulating (e.g., electrically insulating) material, such as silicon oxide, silicon nitride, and/or silicon oxynitride, may be arranged on the substrate 100, and the semiconductor layer 211 may be arranged on the buffer layer 110.

The gate electrode 213 may be arranged on the semiconductor layer 211. The gate electrode 213 may include, for example, at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu) and include a single-layered structure or a multi-layered structure. In one or more embodiments, to secure insulation (e.g., electrical insulation) between the semiconductor layer 211 and the gate electrode 213, a gate insulating layer 120 may be arranged between the semiconductor layer 211 and the gate electrode 213, wherein the gate insulating layer 120 includes an inorganic insulating (e.g., electrically insulating) material, such as silicon oxide, silicon nitride, and/or silicon oxynitride.

An interlayer insulating layer 130 may be arranged on the gate electrode 213. The interlayer insulating layer 130 may include an inorganic insulating (e.g., electrically insulating) material, such as silicon oxide, silicon nitride, and/or silicon oxynitride, and may include a single-layered structure or a multi-layered structure.

The source electrode 215 and the drain electrode 217 may be arranged on the interlayer insulating layer 130. Each of the source electrode 215 and the drain electrode 217 may be electrically connected to the semiconductor layer 211 through a contact hole formed or arranged in the interlayer insulating layer 130 and the gate insulating layer 120. The source electrode 215 and the drain electrode 217 may include at least one selected from among, for example, aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu) by taking into account conductivity (e.g., electrical conductivity) and/or the like, and include a single-layered structure or a multi-layered structure.

A planarization layer 140 may be arranged on the interlayer insulating layer 130. The planarization layer 240 may generally planarize the upper portion of a protective layer that covers the transistor 210. The planarization layer 140 may include an organic insulating (e.g., electrically insulating) material, for example, acryl, benzocyclobutene (BCB), and/or hexamethyldisiloxane (HMDSO). Although it is illustrated in FIG. 7 that the planarization layer 140 is a single layer, the planarization layer 140 may be a multi-layer. However, one or more suitable modifications may be made.

The light-emitting diode 300 may include a pixel electrode 310 on the planarization layer 140, an intermediate layer 320, and an opposite electrode 330, wherein the intermediate layer 320 includes an emission layer.

The pixel electrode 310 may be electrically connected to the transistor 210 through a contact hole defined in the planarization layer 140. The pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a (e.g., any suitable) compound thereof. In one or more embodiments, the pixel electrode 310 may further include a conductive (e.g., electrically conductive) oxide material layer on and/or under the reflective layer. The conductive oxide material layer may include indium tin oxide (ITO), indium zinc oxide (IZO), zinc oxide (e.g., ZnO), indium oxide (e.g., In₂O₃), indium gallium oxide (IGO), and/or aluminum zinc oxide (AZO). In one or more embodiments, the pixel electrode 310 may have a three-layered structure of ITO layer/Ag layer/ITO layer.

A pixel-defining layer 150 may be arranged on the pixel electrode 310. The pixel-defining layer 150 may include an opening that overlaps the pixel electrode 310 and cover the edges of the pixel electrode 310. The pixel-defining layer 150 may include an organic insulating (e.g., electrically insulating) material. The pixel-defining layer 150 may define a pixel by including an opening that exposes the central portion of the pixel electrode 310.

As illustrated in FIG. 7, the pixel-defining layer 150 may prevent arcs and/or the like from occurring (or reduce a degree to or occurrence of which arcs and/or the like occur) at the edges of the pixel electrode 310 by increasing a distance between the edges of the pixel electrode 310 and the opposite electrode 330 over the pixel electrode 310. The pixel-defining layer 150 may include an organic material, such as polyimide and/or HMDSO.

The intermediate layer 320 may include the emission layer. The emission layer may include a low molecular weight material (e.g., a non-polymer material) and/or a high molecular weight material (e.g., a polymer material). The intermediate layer 320 may include a first functional layer and/or a second functional layer, wherein the first functional layer is arranged under the emission layer, and the second functional layer is arranged on the emission layer. The first functional layer may include a hole transport layer (HTL) and/or a hole injection layer (HIL). The second functional layer may include an electron transport layer (ETL) and/or an electron injection layer (EIL). Each of the first functional layer and the second functional layer may include an organic material. In one or more embodiments, the intermediate layer 320 may include a tandem structure including a plurality of stack structures of the first functional layer, the emission layer, and the second functional layer.

The opposite electrode 330 may include a conductive (e.g., electrically conductive) material having a low work function. As an example, the opposite electrode 330 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an (e.g., any suitable) alloy thereof. In one or more embodiments, the opposite electrode 330 may further include a layer on the (semi) transparent layer, the layer including ITO, IZO, ZnO, and/or In₂O₃. The opposite electrode 330 may be integrally formed or arranged over the plurality of light-emitting diodes 300 to correspond to the plurality of pixel electrodes 310.

In order for light to be emitted from the light-emitting diode 300, a voltage is desired or required to be applied to the opposite electrode 330. Accordingly, an electrode power supply line 410 to provide a preset (e.g., set or predetermined) voltage to the opposite electrode 330 may be located or arranged in the peripheral area PA.

If (e.g., when) forming or arranging one or more suitable conductive (e.g., electrically conductive) layers in the display area DA, the electrode power supply line 410 may be concurrently (e.g., simultaneously) formed or arranged using substantially the same material as a material of the one or more suitable conductive (e.g., electrically conductive) layers. In one or more embodiments, the electrode power supply line 410 of FIG. 7 may include substantially the same material as a material of the source electrode 215 or the drain electrode 217 of the transistor 210 and may be located or arranged on substantially the same layer as the source electrode 215 or the drain electrode 217, for example, on the interlayer insulating layer 130.

The opposite electrode 330 may extend to the peripheral area PA and be electrically connected to the electrode power supply line 410. As an example, the opposite electrode 330 may be electrically connected to the electrode power supply line 410 through a conductive layer 420.

The conductive layer 420 may be located or arranged on the planarization layer 140 and may extend on the electrode power supply line 410 to electrically connect the electrode power supply line 410 to the opposite electrode 330. The opposite electrode 330 may be in contact with the conductive layer 420 in the peripheral area PA, and the conductive layer 420 may be in contact with the electrode power supply line 410 in the peripheral area PA. The conductive layer 420 may include substantially the same material as a material of the pixel electrode 310.

A capping layer 160 may be located or arranged on the opposite electrode 330, wherein the capping layer 160 improves or enhances the efficiency of light generated by the light-emitting diode 300. The capping layer 160 may cover the opposite electrode 330 and extend to the outside of the opposite electrode 330 to be in contact with the conductive layer 420 located or arranged under the opposite electrode 330. The opposite electrode 330 may cover the display area DA and extend to the outside of the display area DA, and the capping layer 160 may also cover the display area DA and extend to the peripheral area PA outside the display area DA. The capping layer 160 may include an organic material.

An encapsulation layer 500 may be arranged on the light-emitting diode 300. To prevent damage (or reduce a degree or occurrence of damage) to the capping layer 160 if (e.g., when) forming or arranging the encapsulation layer 500, a protective layer 170 may be arranged between the capping layer 160 and the encapsulation layer 500. The protective layer 170 may include LiF. In an embodiment, an edge 160a of the capping layer 160 may be covered by the protective layer 170. When viewed in a direction perpendicular to an upper surface of the substrate 100, an edge 170a of the protective layer 170 may be located between the edge 160a of the capping layer 160 and an edge 140a of the planarization layer 140.

The encapsulation layer 500 may include an inorganic encapsulation layer and/or an organic encapsulation layer. In one or more embodiments, the encapsulation layer 500 may include a first inorganic encapsulation layer 510, a second inorganic encapsulation layer 530, and an organic encapsulation layer 520, wherein the organic encapsulation layer 520 is between the first inorganic encapsulation layer 510 and the second inorganic encapsulation layer 530.

The first inorganic encapsulation layer 510 and the second inorganic encapsulation layer 530 may (e.g., may each) include at least one inorganic material selected from among aluminum oxide, titanium oxide, tantalum oxide, hafnium oxide, zinc oxide, silicon oxide, silicon nitride, silicon oxynitride, and/or the like. The first inorganic encapsulation layer 510 and the second inorganic encapsulation layer 530 may include a single layer or a multi-layer including the materials as described in one or more embodiments. The organic encapsulation layer 520 may include a polymer-based material. The polymer-based material may include an acryl-based resin, an epoxy-based resin, polyimide, and/or polyethylene. In one or more embodiments, the organic encapsulation layer 520 may include acrylate.

If (e.g., when) forming or arranging the organic encapsulation layer 520, a partition wall may be arranged in the peripheral area PA to remove a flow of a material that forms the organic encapsulation layer 520. As an example, as illustrated in FIG. 7, a first partition wall 610 and a second partition wall 620 may be arranged apart from (e.g., space from) each other in the peripheral area PA. Inorganic insulating (e.g., electrically insulating) layers, such as the buffer layer 110, the gate insulating layer 120, and/or the interlayer insulating layer 130, may extend to the peripheral area PA, and the first partition wall 610 and the second partition wall 620 may be arranged on the inorganic insulating layers.

Each of the first partition wall 610 and the second partition wall 620 may have a multi-layered structure. The first partition wall 610 may include a first layer 611, a second layer 612, and a third layer 613 stacked in a direction (e.g., z direction) normal (e.g., perpendicular) to the upper surface of the substrate 100. The first layer 611 may include substantially the same material as a material of the planarization layer 140, the second layer 612 may include substantially the same material as a material of the pixel-defining layer 150 in the display area DA, and the third layer 613 may include substantially the same material as a material of a spacer that may be arranged on the pixel-defining layer 150 in the display area DA. Each of the first layer 611, the second layer 612, and the third layer 613 may include an organic insulating (e.g., electrically insulating) material. The second partition wall 620 may include a first layer 622 and a second layer 623 stacked in the direction (e.g., z direction) normal (e.g., perpendicular) to the upper surface of the substrate 100. The first layer 622 of the second partition wall 620 may include substantially the same material as a material of the pixel-defining layer 150 in the display area DA, and the second layer 623 may include substantially the same material as a material of the spacer.

The second partition wall 620 may be arranged between the first partition wall 610 and the display area DA. The second partition wall 620 may overlap the electrode power supply line 410. The second partition wall 620 may be located or arranged on a portion of the conductive layer 420 arranged on the electrode power supply line 410. Each of the first partition wall 610 and the second partition wall 620 may be apart from (e.g., space from) the planarization layer 140 and be located or arranged in the peripheral area PA.

As illustrated in FIG. 7, the first inorganic encapsulation layer 510 may cover the first partition wall 610 and the second partition wall 620. The first inorganic encapsulation layer 510 may extend toward an edge 100E of the substrate 100 beyond the first partition wall 610 and the second partition wall 620. The position of the organic encapsulation layer 520 may be limited by the second partition wall 620, and a material to form or arrange the organic encapsulation layer 520 may be prevented from overflowing to the outside of the second partition wall 620 (or a degree to or occurrence of which a material to form or arrange the organic encapsulation layer 520 overflows to the outside of the second partition wall 620 may be reduced) during the process of forming or arranging the organic encapsulation layer 520. Even though the material to form or arrange the organic encapsulation layer 520 partially overflows to the outside of the second partition wall 620, because the position of the organic encapsulation layer 520 is limited by the first partition wall 610, the material to form or arrange the organic encapsulation layer 520 may not move toward the edge 100E of the substrate 100.

In addition to the first partition wall 610 and the second partition wall 620, the uneven structure 630 may be arranged in the peripheral area PA. In the case where the peripheral area PA is bent as described in one or more embodiments with reference to FIGS. 4 to 6, the uneven structure 630 may prevent cracks from occurring (or reduce a degree to or occurrence of which cracks occur) in the peripheral area PA. Even though cracks occur, the uneven structure 630 may prevent the cracks from propagating to the display area DA (or reduce a degree to or occurrence of which the cracks propagate to the display area DA). The uneven structure 630 may include a plurality of protrusions 632 and a plurality of grooves 634. Each of the grooves 634 may be located or arranged between adjacent two protrusions 632. The uneven structure 630 may have a structure in which the protrusions 632 and the grooves 634 are alternately arranged.

The protrusion 632 may have one or more suitable shapes. As illustrated in FIG. 7, the protrusion 632 may include substantially the same material as a material of an element arranged in the display area DA. As an example, the uneven structure 630 may be defined in (or defined by) insulating (e.g., electrically insulating) layers (e.g., inorganic insulating (e.g., electrically insulating) layers) that extend to the peripheral area PA. In one or more embodiments, the inorganic insulating layers, such as the buffer layer 110, the gate insulating layer 120, and the interlayer insulating layer 130, may extend to the peripheral area PA, and the grooves 634 having a preset (e.g., set or predetermined) depth in a thickness direction of the inorganic insulating layers and the protrusions 632 between adjacent grooves 634 may be defined in the inorganic insulating layers. In one or more embodiments, the protrusion 632 may have a multi-layered structure including substantially the same material as a material of each of the buffer layer 110, the gate insulating layer 120, and the interlayer insulating layer 130. In one or more embodiments, a depth of the groove 634 may be substantially equal to a sum of thicknesses of the buffer layer 110, the gate insulating layer 120, and the interlayer insulating layer 130.

As illustrated in FIG. 8, the uneven structure 630 may extend along at least a portion of the edge 100E of the substrate 100 in a plan view. In one or more embodiments, the uneven structure 630 may have a shape that circumnavigates the display area DA. In one or more embodiments, the uneven structure 630 may be around (e.g., surround) the display area DA entirely (e.g., substantially entirely) and have a discontinuous shape in one or more sections.

As an example, the protrusion 632 may extend along at least a portion of the edge 100E of the substrate 100 in a plan view as illustrated in FIG. 8. In one or more embodiments, the protrusion 632 may have a shape that circumnavigates the display area DA. In one or more embodiments, the protrusion 632 may be around (e.g., surround) the display area DA entirely (e.g., substantially entirely) and have a discontinuous shape in one or more sections. As illustrated in FIG. 8, the protrusion 632 may be provided in plurality. The protrusion 632 may include a plurality of protrusions.

A cover bank layer 650 may be arranged on the uneven structure 630. The cover bank layer 650 may include an organic insulating (e.g., electrically insulating) material. In one or more embodiments, the cover bank layer 650 may include substantially the same material as a material of the planarization layer 140. In one or more embodiments, the cover bank layer 650 may cover the edge of the inorganic insulating layers that extend to the peripheral area PA, for example, the edge of each of the buffer layer 110, the gate insulating layer 120, and the interlayer insulating layer 130 and cover the uneven structure 630. A portion of the cover bank layer 650 may at least partially fill the groove 634 of the uneven structure 630.

As illustrated in FIG. 8, the cover bank layer 650 may extend along at least a portion of the edge 100E of the substrate 100 in a plan view. In one or more embodiments, the cover bank layer 650 may have a shape around (e.g., surrounding) the display area DA entirely (e.g., substantially entirely) along the protrusion 632. In one or more embodiments, the cover bank layer 650 may be around (e.g., surround) the display area DA entirely (e.g., substantially entirely) and have a discontinuous shape in one or more sections. The cover bank layer 650 may have a preset (e.g., set or predetermined) width to cover the protrusions 632. The cover bank layer 650 may be apart from (e.g., space from) a partition wall, for example, the first partition wall 610 arranged in the outermost portion.

The inorganic encapsulation layer, for example, each of the first inorganic encapsulation layer 510 and the second inorganic encapsulation layer 530, may extend toward the edge 100E of the substrate 100 beyond the first partition wall 610, the second partition wall 620, the cover bank layer 650, and the uneven structure 630. Edges 510E and 530E of the first inorganic encapsulation layer 510 and the second inorganic encapsulation layer 530 may be apart from (e.g., space from) the edge 100E of the substrate 100.

In one or more embodiments, the edge 510E of the first inorganic encapsulation layer 510 may be located or arranged at a different position from a position of the edge 530E of the second inorganic encapsulation layer 530. As an example, each of the edge 510E of the first inorganic encapsulation layer 510 and the edge 530E of the second inorganic encapsulation layer 530 may be located or arranged between the cover bank layer 650 and the edge 100E of the substrate 100, and the edge 530E of the second inorganic encapsulation layer 530 may be located or arranged between the edge 510E of the first inorganic encapsulation layer 510 and the edge 100E of the substrate 100. Each of the edge 510E of the first inorganic encapsulation layer 510 and the edge 530E of the second inorganic encapsulation layer 530 may be in direct contact with the upper surface of the substrate 100.

The insulating (e.g., electrically insulating) layers located or arranged in the display area DA of the substrate 100, for example, the inorganic insulating layers, may extend to the peripheral area PA as illustrated in FIG. 7 and may not be present between the edge of the inorganic encapsulation layer and the edge 100E of the substrate 100 in the peripheral area PA. As an example, a region between the edge of the inorganic encapsulation layer and the edge 100E of the substrate 100 may be a type (kind) of an inorganic removal region (e.g., an inorganic insulation (e.g., electrical insulation) removal region) NIR where no inorganic material is present on the substrate 100. For example, it is illustrated in FIG. 7 that a space between the edge 530E of the second inorganic encapsulation layer 530 and the edge 100E of the substrate 100 may correspond to the inorganic removal region NIR.

FIG. 9 is a schematic side view of an assembled state of the display device 10 and the lower cover 90 as the electronic apparatus 1 according to one or more embodiments.

The display device 10 of FIG. 9 may be as described in one or more embodiments with reference to FIG. 7. Because the uneven structure 630 includes the structure in which the protrusions 632 and the grooves 634 are alternately arranged, cracks that may occur due to stress applied to the display device 10 while the display device 10 is bent may be prevented from penetrating the display area DA (or a degree to or occurrence of which cracks that may occur due to stress applied to the display device 10 while the display device 10 is bent penetrate the display area DA may be reduced).

As a comparative example, in the case where the uneven structure 630 and the cover bank layer 650 are apart from (e.g., space from) the first inorganic encapsulation layer 510 and the second inorganic encapsulation layer 530 to prevent cracks from propagating (or to reduce a degree to or occurrence of which cracks propagate), because a space for arrangement of the uneven structure 630 and the cover bank layer 650 is separately prepared, the width of the peripheral area PA may increase. However, as in the display device 10 according to one or more embodiments as illustrated in FIGS. 7 and 9, in the case where the uneven structure 630 and the cover bank layer 650 overlap the first inorganic encapsulation layer 510 and the second inorganic encapsulation layer 530, the width of the peripheral area PA may be reduced and the space of the display device 10 may be effectively or suitably used.

In one or more embodiments, because the cover bank layer 650 separates the first inorganic encapsulation layer 510 and the second inorganic encapsulation layer 530 from the uneven structure 630, even though cracks occur in the protrusions 632 of the uneven structure 630 due to stress applied to the display device 1 while the display device 10 is bent, the cracks may be prevented from propagating (or a degree to or occurrence of which the cracks propagate may be reduced) to the first inorganic encapsulation layer 510 and the second inorganic encapsulation layer 530.

As illustrated in FIG. 9, the display device 10 may be assembled to the lower cover 90 while being bent such that a portion of the peripheral area PA, for example, the inorganic removal region NIR, has a preset (e.g., set or predetermined) curvature. The inorganic removal region NIR may correspond to the second bent region BR2 as described in one or more embodiments with reference to FIG. 6. A portion of the display device 10, for example, the inorganic removal region NIR or the second bent region BR2, may overlap the lower cover 90.

A layer including the inorganic insulating (e.g., electrically insulating) material may be relatively susceptible to damage by stresses applied to the display device 10 while the display device 10 is bent, but because not only the first inorganic encapsulation layer 510 and the second inorganic encapsulation layer 530 but also the inorganic insulating layers that may be arranged between the substrate 100 and the first inorganic encapsulation layer 510, for example, the buffer layer 110, the gate insulating layer 120, and the interlayer insulating layer 130 are not present in the inorganic removal region NIR, the issues as described in one or more embodiments may be prevented or reduced. For example, because the inorganic removal region NIR is provided or arranged between the edge 100E of the substrate 100 and the edge (edge 530E of the second inorganic encapsulation layer 530) of the inorganic encapsulation layer as in one or more embodiments, cracks may be effectively or suitably prevented from occurring due to stresses applied while the second bent region BR2 is bent (or a degree to or occurrence of which cracks occur due to stresses applied while the second bent region BR2 is bent may be effectively or suitably reduced).

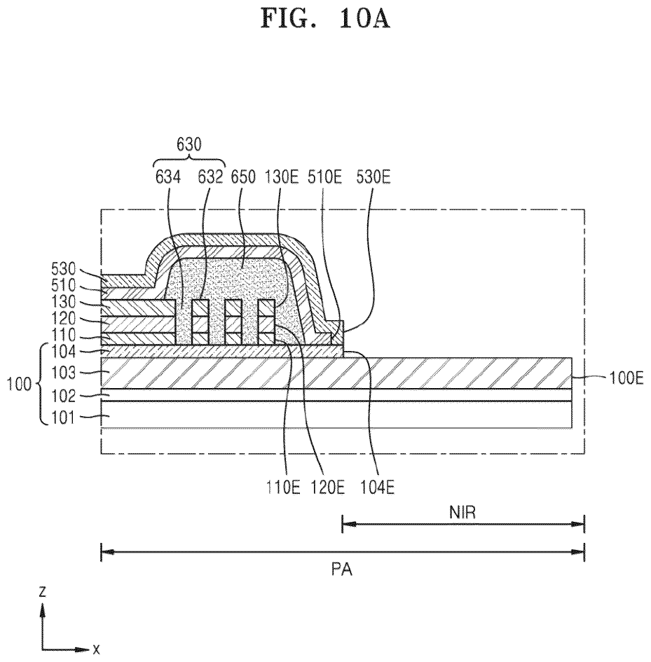

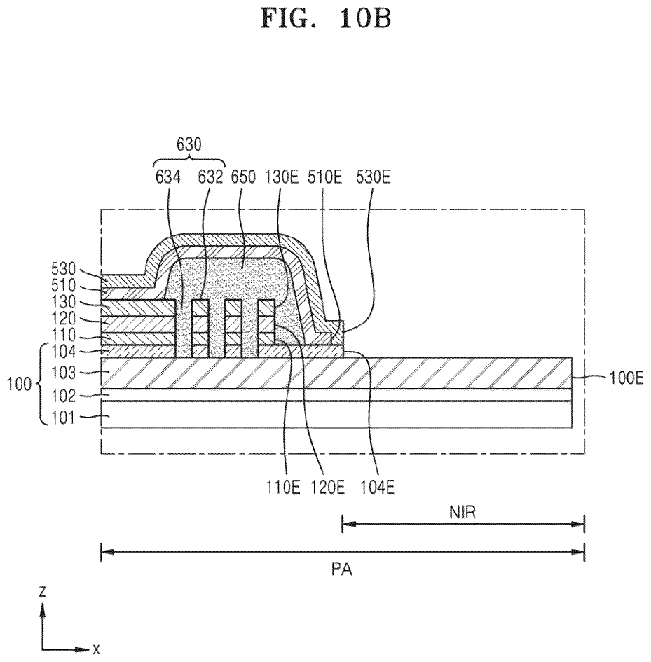

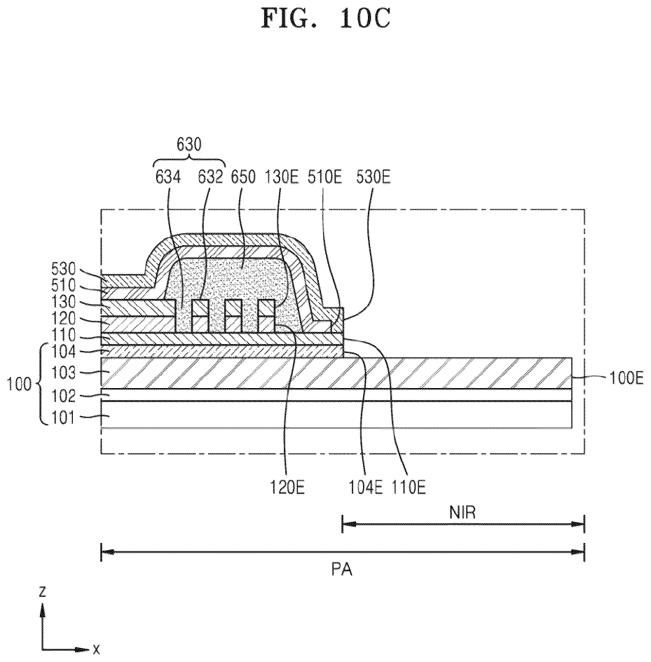

FIGS. 10A to 10C are cross-sectional views each being of the uneven structure 630 and the cover bank layer 650 of the display device 10 according to one or more embodiments.

The uneven structure 630 may have a structure in which the protrusions 632 and the grooves 634 are alternately arranged. The uneven structure 630 may be defined in (or defined by) the inorganic insulating layers that extend to the peripheral area PA, and the inorganic insulating layers may include the buffer layer 110, the gate insulating layer 120, and the interlayer insulating layer 130.

It is illustrated in FIG. 10A that the inorganic insulating (e.g., electrically insulating) layers of the buffer layer 110, the gate insulating layer 120, and the interlayer insulating layer 130 may extend to the peripheral area PA, and the uneven structure 630 may be defined in (or defined by) the inorganic insulating layers. As an example, the protrusion 632 may have a multi-layered structure including substantially the same material as a material of each of the buffer layer 110, the gate insulating layer 120, and the interlayer insulating layer 130. The depth of the groove 634 may be substantially equal to a sum of thicknesses of the buffer layer 110, the gate insulating layer 120, and the interlayer insulating layer 130.

In one or more embodiments, edges 110E, 120E, and 130E of the buffer layer 110, the gate insulating layer 120, and the interlayer insulating layer 130 may be located or arranged closer to the display area DA (see FIG. 7) than the edge 510E of the first inorganic encapsulation layer 510 and be covered by the cover bank layer 650.

In one or more embodiments, the substrate 100 may include a first polymer resin layer 101, a first inorganic barrier layer 102 on the first polymer resin layer 101, a second polymer resin layer 103 on the first inorganic barrier layer 102, and a second inorganic barrier layer 104 on the second polymer resin layer 103. In one or more embodiments, as illustrated in FIG. 10A, the bottom surface of the groove 634 may be substantially equal to (or correspond to) the upper surface of the substrate 100, for example, the upper surface of the second inorganic barrier layer 104.

The inorganic removal region NIR may be formed or arranged by removing a portion of the inorganic insulating (e.g., electrically insulating) layer arranged in the inorganic removal region NIR. As an example, the inorganic removal region NIR may be formed or arranged by forming or arranging, on the substrate 100, the uneven structure 630, the cover bank layer 650, the first inorganic encapsulation layer 510, and the second inorganic encapsulation layer 530, and then etching a portion of each of the first inorganic encapsulation layer 510 and the second inorganic encapsulation layer 530 that correspond to the inorganic removal region NIR. During the etching process of removing a portion of each of the first inorganic encapsulation layer 510 and the second inorganic encapsulation layer 530, a portion of a layer, for example, the second inorganic barrier layer 104, located or arranged under the first inorganic encapsulation layer 510 and the second inorganic encapsulation layer 530, and including an inorganic insulating (e.g., electrically insulating) material, may also be etched. In one or more embodiments, as illustrated in FIG. 10A, an edge 104E of the second inorganic barrier layer 104 may be substantially aligned on the same line as the edge 530E of the second inorganic encapsulation layer 530. In the case where a portion of the second inorganic barrier layer 104 is removed, the edge 100E of the substrate 100 may be defined as an edge of at least one selected from among the first polymer resin layer 101, the first inorganic barrier layer 102, and/or the second polymer resin layer 103.

For example, the inorganic removal region NIR may be created by removing parts of the inorganic insulating layer in the inorganic removal region NIR. This may involve forming structures on the substrate 100, including the uneven structure 630, the cover bank layer 650, and the first and second inorganic encapsulation layers 510 and 530. Portions of these encapsulation layers may then be etched away. During this etching process, parts of the underlying second inorganic barrier layer 104 may also be removed. In one or more embodiments, the edges 104E and 530E of the barrier layer 104 and the second inorganic encapsulation layer 530 may align. If (e.g., when) part of the second inorganic barrier layer 104 is removed, the edge 100E of the substrate 100 may be defined by the edges of selected polymer resin layers 101 and/or 103 and/or the inorganic barrier layer 102.

Although it is illustrated in FIG. 10A that the depth of the groove 634 of the uneven structure 630 is substantially equal to a sum of the thicknesses of the buffer layer 110, the gate insulating layer 120, and the interlayer insulating layer 130, embodiments of the present disclosure are not limited thereto. In one or more embodiments, as illustrated in FIG. 10B, the groove 634 may extend toward the second inorganic barrier layer 104 of the substrate 100. In one or more embodiments, the depth of the groove 634 may be substantially equal to a sum of thicknesses of the second inorganic barrier layer 104, the buffer layer 110, the gate insulating layer 120, and the interlayer insulating layer 130. The bottom surface of the groove 634 may be substantially equal to the upper surface of the second polymer resin layer 103. Because the groove 634 extends up to the second inorganic barrier layer 104, the protrusion 632 may have a multi-layered structure including substantially the same material as a material of each of the second inorganic barrier layer 104, the buffer layer 110, the gate insulating layer 120, and the interlayer insulating layer 130.

Although it is illustrated in FIG. 10A that the depth of the groove 634 of the uneven structure 630 is substantially equal to a sum of the thicknesses of the buffer layer 110, the gate insulating layer 120, and the interlayer insulating layer 130, embodiments of the present disclosure are not limited thereto. In one or more embodiments, as illustrated in FIG. 10C, the depth of the groove 634 may be substantially equal to a sum of thicknesses of the gate insulating layer 120 and the interlayer insulating layer 130. In one or more embodiments, the bottom surface of the groove 634 may be substantially equal to (or correspond to) the upper surface of the buffer layer 110. The protrusion 632 may have a multi-layered structure including substantially the same material as a material of each of the gate insulating layer 120 and the interlayer insulating layer 130.

For example, the uneven structure 630 may be defined in the inorganic insulating (e.g., electrically insulating) layers including the buffer layer 110, the gate insulating layer 120, and the interlayer insulating layer 130, and the depth of the groove 634 may be less than a sum of the thicknesses of the inorganic insulating layers as described in one or more embodiments. As an example, upper layers (e.g., upper layers including substantially the same material as a material of the gate insulating layer 120 and/or the interlayer insulating layer 130) of the protrusions 632 adjacent to each other with the groove 634 therebetween may be apart from (e.g., space from) each other, and lower layers (e.g., lower layers including substantially the same material as a material of the buffer layer 110) of the protrusions 632 adjacent to each other may be connected to each other.

In one or more embodiments, during the etching process of removing a portion of the first inorganic encapsulation layer 510 and the second inorganic encapsulation layer 530 to form or arrange the inorganic removal region NIR, a portion of the buffer layer 110 and a portion of the second inorganic barrier layer 104 may be removed. In one or more embodiments, the edge 110E of the buffer layer 110 and the edge 104E of the second inorganic barrier layer 104 may be substantially aligned on the same line as the edge 530E of the second inorganic encapsulation layer 530.

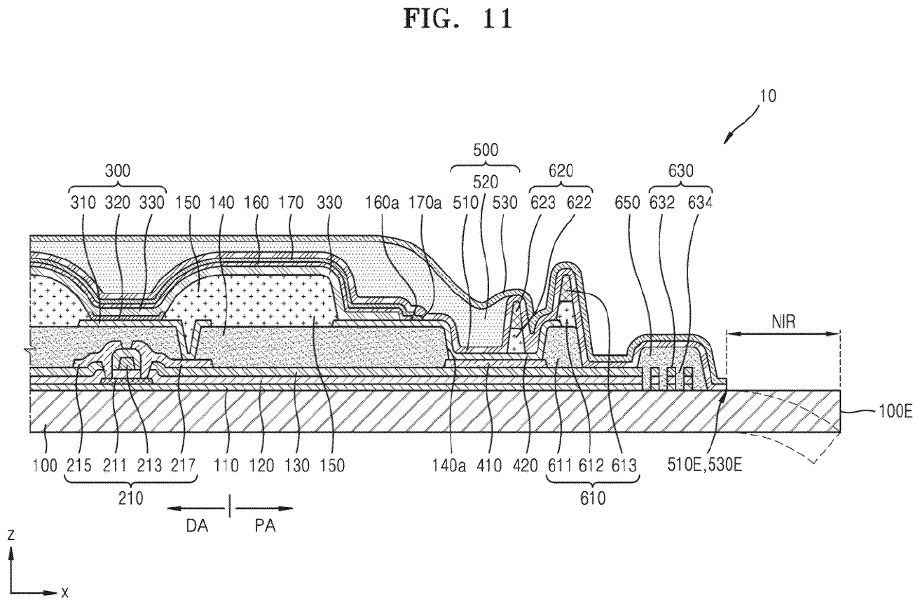

FIG. 11 is a schematic cross-sectional view of the display device 10 according to one or more embodiments.

The display device 10 as illustrated in FIG. 11 may have substantially the same structure as a structure of one or more embodiments as described in one or more embodiments with reference to FIG. 7. A portion, for example, the insulation (e.g., electrical insulation) removal region (e.g., inorganic removal region NIR NIR) of the peripheral area PA of the display device 10 as illustrated in FIG. 11 may be bent with a preset (e.g., set or predetermined) curvature and may overlap the lower cover 90 (see FIG. 9) as described in one or more embodiments with reference to FIG. 9. In one or more embodiments as illustrated in FIG. 11, there may be a difference in the positions of the edges 510E and 530E of the first inorganic encapsulation layer 510 and the second inorganic encapsulation layer 530. The difference is mainly or predominantly described in more detail herein.

Referring to FIG. 11, the inorganic encapsulation layer, for example, each of the first inorganic encapsulation layer 510 and the second inorganic encapsulation layer 530 may extend toward the edge 100E of the substrate 100 beyond the first partition wall 610, the second partition wall 620, the cover bank layer 650, and the uneven structure 630. The edges 510E and 530E of the first inorganic encapsulation layer 510 and the second inorganic encapsulation layer 530 may be apart from (e.g., space from) the edge 100E of the substrate 100 and be substantially aligned on the same line.

The edge 510E of the first inorganic encapsulation layer 510 and the edge 530E of the second inorganic encapsulation layer 530 may be located or arranged between the cover bank layer 650 and the edge 100E of the substrate 100 and be substantially aligned on the same line.

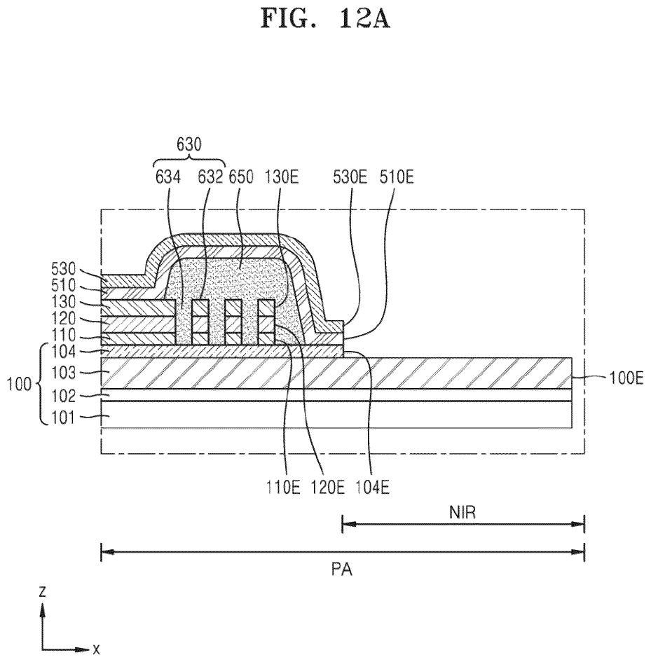

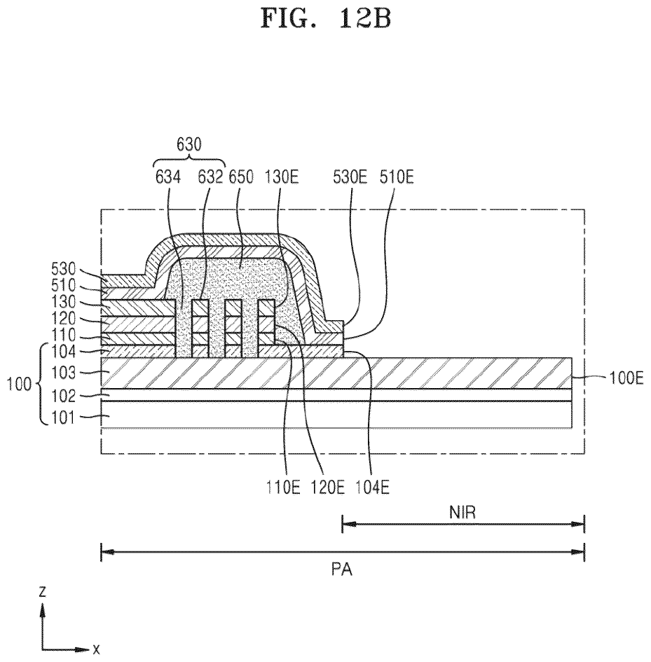

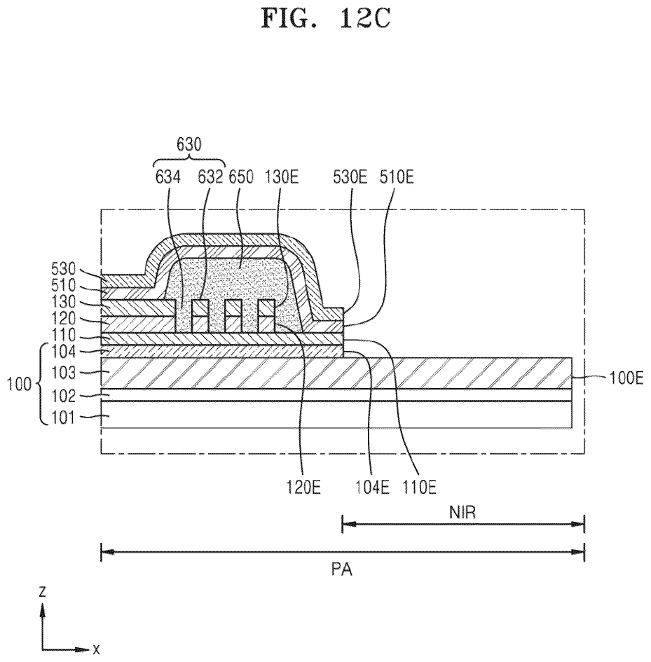

FIGS. 12A to 12C are cross-sectional views each being of the uneven structure 630 and the cover bank layer 650 of the display device 10 according to one or more embodiments.

The uneven structure 630 may have a structure in which the protrusions 632 and the grooves 634 are alternately arranged. The uneven structure 630 may be defined by the inorganic insulating layers that extend to the peripheral area PA, and the inorganic insulating layers may include the buffer layer 110, the gate insulating layer 120, and the interlayer insulating layer 130.

Referring to FIG. 12A, the inorganic insulating (e.g., electrically insulating) layers of the buffer layer 110, the gate insulating layer 120, and the interlayer insulating layer 130 may extend to the peripheral area PA, and the uneven structure 630 may be defined by the inorganic insulating layers. In one or more embodiments, the protrusion 632 may have a multi-layered structure including substantially the same material as a material of each of the buffer layer 110, the gate insulating layer 120, and the interlayer insulating layer 130. The depth of the groove 634 may be substantially equal to a sum of thicknesses of the buffer layer 110, the gate insulating layer 120, and the interlayer insulating layer 130.

The edges 110E, 120E, and 130E of the buffer layer 110, the gate insulating layer 120, and the interlayer insulating layer 130 may be located or arranged closer to the display area DA (see FIG. 7) than the edge 510E of the first inorganic encapsulation layer 510 and be covered by the cover bank layer 650.

The inorganic removal region NIR may be formed or arranged by removing a portion of the inorganic insulating layer arranged in the inorganic removal region NIR. As an example, the inorganic removal region NIR may be formed or arranged by forming or arranging, on the substrate 100, the uneven structure 630, the cover bank layer 650, the first inorganic encapsulation layer 510, and the second inorganic encapsulation layer 530, and then etching a portion of each of the first inorganic encapsulation layer 510 and the second inorganic encapsulation layer 530 that correspond to the inorganic removal region NIR.

In one or more embodiments, the substrate 100 may include a first polymer resin layer 101, a first inorganic barrier layer 102 on the first polymer resin layer 101, a second polymer resin layer 103 on the first inorganic barrier layer 102, and a second inorganic barrier layer 104 on the second polymer resin layer 103. In an etching process of removing a portion of each of the first inorganic encapsulation layer 510 and the second inorganic encapsulation layer 530 to form or arrange the inorganic removal region NIR, a portion of the second inorganic barrier layer 104 may also be removed. Accordingly, the edge 104E of the second inorganic barrier layer 104 may be substantially aligned on the same line as the edges 510E and 530E of the first inorganic encapsulation layer 510 and the second inorganic encapsulation layer 530. In the case where a portion of the second inorganic barrier layer 104 is removed through etching, the edge 100E of the substrate 100 may be defined as an edge of at least one selected from among the first polymer resin layer 101, the first inorganic barrier layer 102, and the second polymer resin layer 103.

An etching process of forming or arranging the insulation removal region (e.g., inorganic removal region NIR) may include forming or arranging each of the first inorganic encapsulation layer 510 and the second inorganic encapsulation layer 530 to cover the substrate 100 entirely (e.g., substantially entirely), and then removing a portion of each of the first inorganic encapsulation layer 510 and the second inorganic encapsulation layer 530 that correspond to the inorganic removal region NIR. In one or more embodiments, because a portion of the first inorganic encapsulation layer 510, a portion of the second inorganic encapsulation layer 530, and the second inorganic barrier layer 104 also have a substantially uniform thickness, damage to the second polymer resin layer 103 that may occur during the etching process may be reduced. In one or more embodiments, the edge 510E of the first inorganic encapsulation layer 510, the edge 530E of the second inorganic encapsulation layer 530, and the edge 104E of the second inorganic barrier layer 104 may be substantially aligned on the same line.

Although it is illustrated in FIG. 12A that the depth of the groove 634 of the uneven structure 630 is substantially equal to a sum of the thicknesses of the buffer layer 110, the gate insulating layer 120, and the interlayer insulating layer 130, embodiments of the present disclosure are not limited thereto. In one or more embodiments, as illustrated in FIG. 12B, the groove 634 may extend toward the second inorganic barrier layer 104 of the substrate 100. In one or more embodiments, the depth of the groove 634 may be substantially equal to a sum of thicknesses of the second inorganic barrier layer 104, the buffer layer 110, the gate insulating layer 120, and the interlayer insulating layer 130. The bottom surface of the groove 634 may be substantially equal to the upper surface of the second polymer resin layer 103.

Although it is illustrated in FIG. 12A that the depth of the groove 634 of the uneven structure 630 is substantially equal to a sum of the thicknesses of the buffer layer 110, the gate insulating layer 120, and the interlayer insulating layer 130, embodiments of the present disclosure are not limited thereto. In one or more embodiments, as illustrated in FIG. 12C, the depth of the groove 634 may be substantially equal to a sum of thicknesses of the gate insulating layer 120 and the interlayer insulating layer 130. In one or more embodiments, the bottom surface of the groove 634 may be substantially equal to the upper surface of the buffer layer 110. The protrusion 632 may have a multi-layered structure including substantially the same material as a material of each of the gate insulating layer 120 and the interlayer insulating layer 130.

For example, the uneven structure 630 may be defined in (or defined by) the inorganic insulating (e.g., electrically insulating) layers including the buffer layer 110, the gate insulating layer 120, and the interlayer insulating layer 130, and the depth of the groove 634 may be less than a sum of the thicknesses of the inorganic insulating layers as described in one or more embodiments. As an example, upper layers (e.g., upper layers including substantially the same material as a material of the gate insulating layer 120 and/or the interlayer insulating layer 130) of the protrusions 632 adjacent to each other with the groove 634 therebetween may be apart from (e.g., space from) each other, and lower layers (e.g., lower layers including substantially the same material as a material of the buffer layer 110) of the protrusions 632 adjacent to each other may be connected to each other.

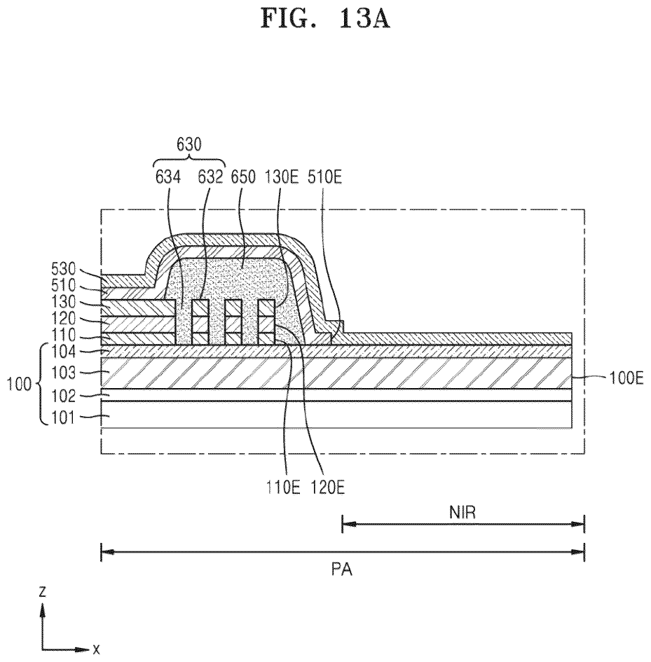

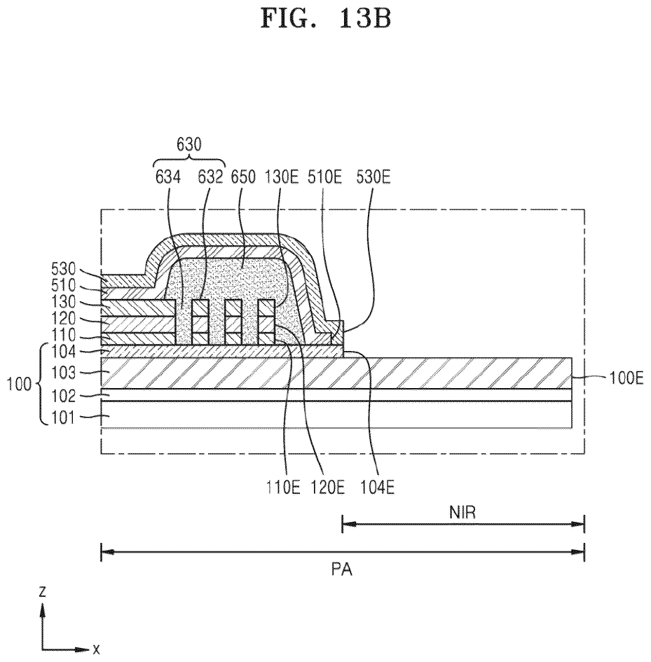

FIGS. 13A and 13B are cross-sectional views illustrating a process of manufacturing the display device 10 according to one or more embodiments.

Referring to FIG. 7, the process of manufacturing the display device 10 may include forming or arranging, in the display area DA of the substrate 100, the transistors 210 and the light-emitting diodes 300 electrically connected to the transistors 210, forming or arranging partition walls (e.g., the first partition wall 610 and the second partition wall 620) located or arranged in the peripheral area PA of the substrate 100, forming or arranging the uneven structure 630 between the partition walls and the edge 100E of the substrate 100, and forming or arranging the cover bank layer 650 on the uneven structure 630. Next, a process of forming or arranging the encapsulation layer 500 may be included. For example, FIG. 13A illustrates the uneven structure 630 and the encapsulation layer 500 on the cover bank layer 650 arranged in the peripheral area PA.

The process of forming or arranging the encapsulation layer 500 may include forming or arranging the first inorganic encapsulation layer 510, forming or arranging the organic encapsulation layer 520, and forming or arranging the second inorganic encapsulation layer 530. The first inorganic encapsulation layer 510 and the second inorganic encapsulation layer 530 may be formed or arranged using different masks. In one or more embodiments, an opening of a mask to form or arrange the first inorganic encapsulation layer 510 may be less than an opening of a mask to form or arrange the second inorganic encapsulation layer 530. In one or more embodiments, the first inorganic encapsulation layer 510 may be formed or arranged by using a mask having an opening that corresponds to an area in which the first inorganic encapsulation layer 510 is located or arranged, but the second inorganic encapsulation layer 530 may be formed or arranged without a mask. Accordingly, during the process of forming or arranging the second inorganic encapsulation layer 530, the second inorganic encapsulation layer 530 may extend up to the edge 100E of the substrate 100 beyond the edge 510E of the first inorganic encapsulation layer 510.

Next, as illustrated in FIG. 13B, the inorganic removal region NIR may be formed or arranged by removing a portion of the second inorganic encapsulation layer 530. A portion of the second inorganic encapsulation layer 530 may be removed by an etching process.

In one or more embodiments, in the case where the substrate 100 includes the first polymer resin layer 101, the first inorganic barrier layer 102 on the first polymer resin layer 101, the second polymer resin layer 103 on the first inorganic barrier layer 102, and the second inorganic barrier layer 104 on the second polymer resin layer 103, a portion of the second inorganic barrier layer 104 provided or arranged on the uppermost layer of the substrate 100 may also be removed during the etching process. For example, it is illustrated in FIG. 13B that the edge 104E of the second inorganic barrier layer 104 and the edge 530E of the second inorganic encapsulation layer 530 are substantially aligned on the same line. The edge 530E of the second inorganic encapsulation layer 530 may be located or arranged between the edge 510E of the first inorganic encapsulation layer 510 and the edge 100E (e.g., edge of the second polymer resin layer 103) of the substrate 100.

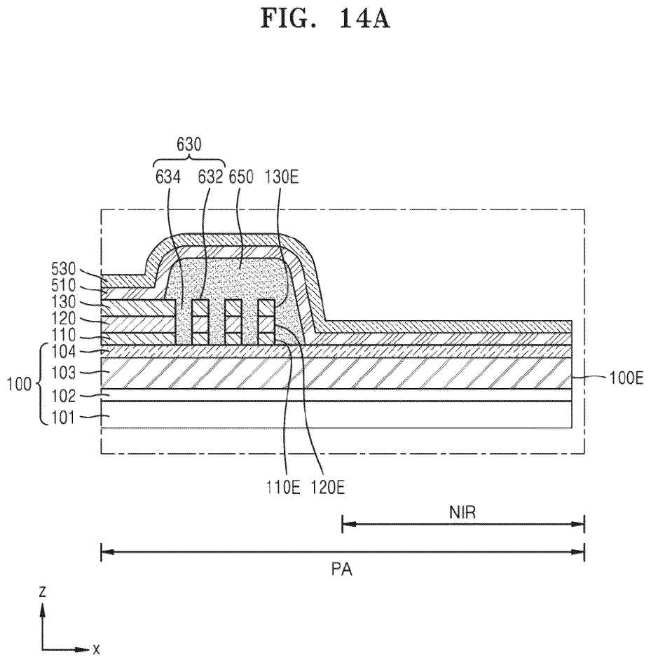

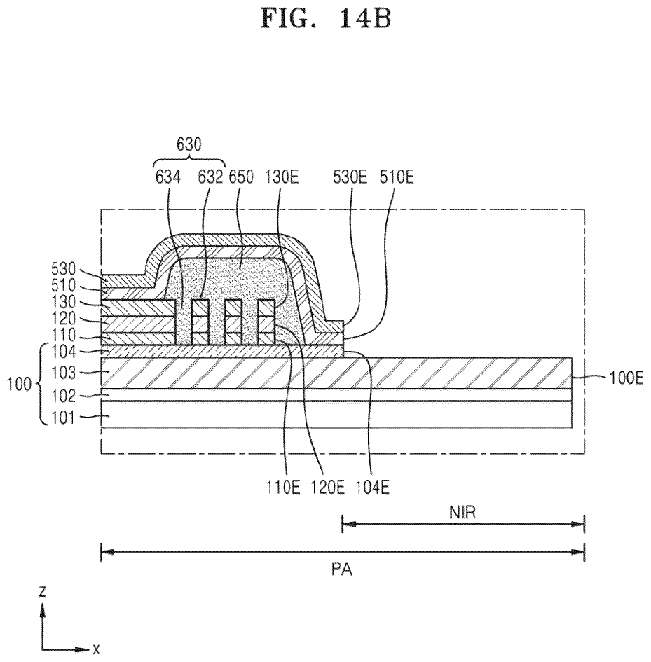

FIGS. 14A and 14B are cross-sectional views illustrating a process of manufacturing the display device 10 according to one or more embodiments.

Referring to FIG. 7, the process of manufacturing the display device 10 may include forming or arranging, in the display area DA of the substrate 100, the transistors 210 and the light-emitting diodes 300 electrically connected to the transistors 210, forming or arranging partition walls (e.g., the first partition wall 610 and the second partition wall 620) located or arranged in the peripheral area PA of the substrate 100, forming or arranging the uneven structure 630 between the partition walls and the edge 100E of the substrate 100, and forming or arranging the cover bank layer 650 on the uneven structure 630. Next, a process of forming or arranging the encapsulation layer 500 may be included. For example, FIG. 14A illustrates the uneven structure 630 and the encapsulation layer 500 on the cover bank layer 650 arranged in the peripheral area PA.

The process of forming or arranging the encapsulation layer 500 may include forming or arranging the first inorganic encapsulation layer 510, forming or arranging the organic encapsulation layer 520, and forming or arranging the second inorganic encapsulation layer 530. The first inorganic encapsulation layer 510 and the second inorganic encapsulation layer 530 may be formed or arranged using substantially the same mask, or formed or arranged to cover the substrate 100 entirely (e.g., substantially entirely) without a mask. Accordingly, as illustrated in FIG. 14A, a portion of the second inorganic encapsulation layer 530 may continuously (e.g., substantially continuously) extend between the uneven structure 630 and the edge 100E of the substrate 100 while overlapping a portion of the first inorganic encapsulation layer 510.

Next, as illustrated in FIG. 14B, the inorganic removal region NIR may be formed or arranged by removing a portion of the second inorganic encapsulation layer 530. The process of removing a portion of the second inorganic encapsulation layer 530 may include removing a portion of the first inorganic encapsulation layer 510 thereunder. For example, a portion of the second inorganic encapsulation layer 530 and a portion of the first inorganic encapsulation layer 510 may be removed together during substantially the same process. A portion of the second inorganic encapsulation layer 530 and a portion of the first inorganic encapsulation layer 510 may be removed by an etching process.

In one or more embodiments, in the case where the substrate 100 includes the first polymer resin layer 101, the first inorganic barrier layer 102 on the first polymer resin layer 101, the second polymer resin layer 103 on the first inorganic barrier layer 102, and the second inorganic barrier layer 104 on the second polymer resin layer 103, a portion of the second inorganic barrier layer 104 provided or arranged on the uppermost layer of the substrate 100 may also be removed during the etching process. The edge 104E of the second inorganic barrier layer 104, the edge 510E of the first inorganic encapsulation layer 510, and the edge 530E of the second inorganic encapsulation layer 530 formed or arranged while being removed in substantially the same process may be substantially aligned on the same line as illustrated in FIG. 14B.

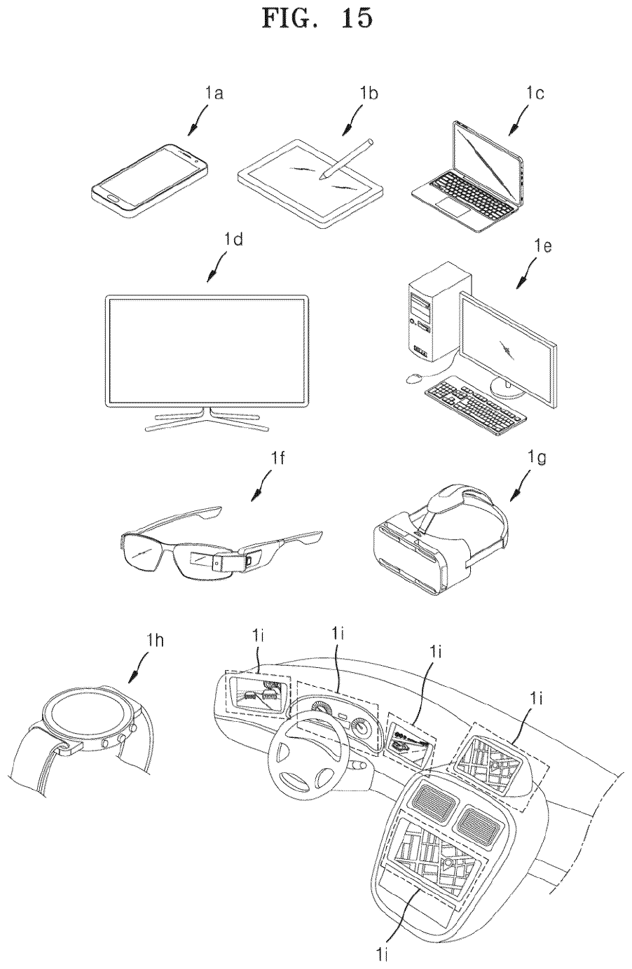

FIG. 15 is a perspective view of an electronic apparatus that employs the display device 10 according to one or more embodiments.

Referring to FIG. 15, an electronic apparatus that employs the display device according to one or more embodiments may include not only electronic apparatuses to display images, such as a smartphone 1a, a tablet personal computer (PC) 1b, a laptop 1c, a TV 1d, and/or a desk monitor 1e, but also wearable electronic apparatuses including a display module, such as a smartglasses 1f, a head mount display 1g, and/or a smartwatch 1h, and/or vehicle electronic apparatuses 1i including a display module, such as an instrument panel of an automobile, a center facia, a center information display (CID) arranged on a dashboard, and/or a room mirror display.

According to one or more embodiments, a display device in which defect occurrence during the manufacturing process is prevented or reduced and an electronic apparatus including the display device may be provided. The aspects and features of embodiments of the present disclosure are just examples and are not limited thereto.

For example, a display device designed to prevent or reduce defects during the manufacturing process and an electronic apparatus including such a display device may be provided. This display device may include a substrate with a display area and a peripheral area, transistors and light-emitting diodes in the display area, and an encapsulation layer including a first inorganic layer and a second inorganic layer with an organic layer in between. In the peripheral area, there may be inorganic insulating (e.g., electrically insulating) layers, a partition wall, and an uneven structure with protrusions and grooves, covered by a cover bank layer. The edges of the encapsulation layers and the inorganic insulatin may be strategically positioned to enhance durability and performance. The aspects and features described are examples and not limiting to the embodiments of the present disclosure.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device using a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

It should be understood that embodiments described herein should be considered in a descriptive sense only and not for purposes of limitation. Descriptions of features or aspects within each embodiment should typically be considered as available for other similar features or aspects in other embodiments. While the subject matter of the present disclosure have been described with reference to the drawings, it will be understood by those of ordinary skill in the art that one or more suitable changes in form and more details may be made therein without departing from the spirit and scope as defined by the following claims and equivalents thereof.

What is claimed is:

1. A display device, comprising:
a substrate comprising a display area and a peripheral area outside the display area;
a plurality of transistors in the display area of the substrate;
a plurality of light-emitting diodes arranged in the display area of the substrate and electrically connected to the plurality of transistors;
an encapsulation layer arranged on the plurality of light-emitting diodes and comprising a first inorganic encapsulation layer, a second inorganic encapsulation layer over the first inorganic encapsulation layer, and an organic encapsulation layer between the first inorganic encapsulation layer and the second inorganic encapsulation layer;
a plurality of inorganic insulating layers arranged in the peripheral area of the substrate and apart from an edge of the substrate;
a partition wall in the peripheral area of the substrate;
an uneven structure arranged between the partition wall and the edge of the substrate, defined in the plurality of inorganic insulating layers, and comprising a plurality of protrusions and a groove between two adjacent protrusions selected from among the plurality of protrusions; and
a cover bank layer on the uneven structure,
wherein an edge of the organic encapsulation layer is on one side of the partition wall, and each of the first inorganic encapsulation layer and the second inorganic encapsulation layer extends on the cover bank layer and is apart from the edge of the substrate.

2. The display device as claimed in claim 1, wherein an edge of the second inorganic encapsulation layer is between an edge of the first inorganic encapsulation layer and the edge of the substrate.

3. The display device as claimed in claim 1, wherein an edge of the first inorganic encapsulation layer and an edge of the second inorganic encapsulation layer are substantially aligned on the same line.

4. The display device as claimed in claim 1, wherein the first inorganic encapsulation layer is in direct contact with the second inorganic encapsulation layer, on the cover bank layer.

5. The display device as claimed in claim 1, wherein the plurality of inorganic insulating layers comprise a buffer layer between the substrate and a semiconductor layer of each of the plurality of transistors, and an edge of the buffer layer is apart from the edge of the substrate.

6. The display device as claimed in claim 5, wherein a bottom surface of the groove corresponds to an upper surface of the buffer layer.

7. The display device as claimed in claim 5, wherein a bottom surface of the groove corresponds to an upper surface of the substrate.

8. The display device as claimed in claim 1, wherein the substrate comprises:
a first polymer resin layer;
a first inorganic barrier layer on the first polymer resin layer;
a second polymer resin layer on the first inorganic barrier layer; and
a second inorganic barrier layer on the second polymer resin layer,
wherein the edge of the substrate is defined by an edge of at least one of the first polymer resin layer, the first inorganic barrier layer, or the second polymer resin layer, and
wherein an edge of the second inorganic barrier layer is apart from the edge of the at least one of the first polymer resin layer, the first inorganic barrier layer, or the second polymer resin layer.

9. The display device as claimed in claim 8, wherein the groove extends to the second inorganic barrier layer.

10. The display device as claimed in claim 8, wherein an edge of the second inorganic encapsulation layer and the edge of the second inorganic barrier layer are substantially aligned on the same line.

11. An electronic apparatus, comprising:
a display device comprising a display area and a peripheral area; and
a lower cover forming an exterior, the lower cover comprising, in a front surface of the lower cover, an opening exposing a portion of the display device, and the lower cover overlapping the peripheral area of the display device,
wherein the display device comprises:
a substrate;
a plurality of transistors on the substrate to correspond to the display area;
a plurality of light-emitting diodes arranged on the substrate to correspond to the display area and electrically connected to the plurality of transistors;
an encapsulation layer arranged on the plurality of light-emitting diodes and comprising a first inorganic encapsulation layer, a second inorganic encapsulation layer over the first inorganic encapsulation layer, and an organic encapsulation layer between the first inorganic encapsulation layer and the second inorganic encapsulation layer;
a plurality of inorganic insulating layers arranged in the peripheral area of the substrate and apart from an edge of the substrate;
a partition wall in the peripheral area of the substrate;
an uneven structure arranged between the partition wall and the edge of the substrate, defined in the plurality of inorganic insulating layers, and comprising a plurality of protrusions and a groove between two adjacent protrusions selected from among the plurality of protrusions; and
a cover bank layer on the uneven structure,
wherein an edge of the organic encapsulation layer is on one side of the partition wall, and each of the first inorganic encapsulation layer and the second inorganic encapsulation layer extends on the cover bank layer, and an edge of the first inorganic encapsulation layer and an edge of the second inorganic encapsulation layer are apart from the edge of the substrate, and
wherein a portion of a region of the substrate that corresponds to the peripheral area is bent to have curvature.

12. The electronic apparatus as claimed in claim 11, wherein the edge of the second inorganic encapsulation layer is between the edge of the first inorganic encapsulation layer and the edge of the substrate.

13. The electronic apparatus as claimed in claim 11, wherein the edge of the first inorganic encapsulation layer and the edge of the second inorganic encapsulation layer are substantially aligned on the same line.

14. The electronic apparatus as claimed in claim 11, wherein the first inorganic encapsulation layer is in direct contact with the second inorganic encapsulation layer, on the cover bank layer.

15. The electronic apparatus as claimed in claim 11, wherein the plurality of inorganic insulating layers comprise a buffer layer between the substrate and a semiconductor layer of each of the plurality of transistors, and an edge of the buffer layer is apart from the edge of the substrate.

16. The electronic apparatus as claimed in claim 15, wherein a bottom surface of the groove corresponds to an upper surface of the buffer layer.

17. The electronic apparatus as claimed in claim 15, wherein a bottom surface of the groove corresponds to an upper surface of the substrate.

18. The electronic apparatus as claimed in claim 11, wherein the substrate comprises:
a first polymer resin layer;
a first inorganic barrier layer on the first polymer resin layer;
a second polymer resin layer on the first inorganic barrier layer; and
a second inorganic barrier layer on the second polymer resin layer,
wherein the edge of the substrate is defined by an edge of at least one of the first polymer resin layer, the first inorganic barrier layer, or the second polymer resin layer, and
wherein an edge of the second inorganic barrier layer is apart from the edge of the at least one of the first polymer resin layer, the first inorganic barrier layer, or the second polymer resin layer.

19. The electronic apparatus as claimed in claim 18, wherein the edge of the second inorganic encapsulation layer and the edge of the second inorganic barrier layer are substantially aligned on the same line.

20. The electronic apparatus as claimed in claim 18, wherein the groove extends to the second inorganic barrier layer.
